(19) United States
(12) Patent Application Publication
(10) Pub. No.: US 2026/0262503 A1
(43) Pub. Date: Sep. 3, 2026

(54) MARCHAND BALUNS IN PACKAGE SUBSTRATES

(71) Applicant: TEXAS INSTRUMENTS INCORPORATED, Dallas, TX (US)

(72) Inventors: Harshpreet Singh Phull BAKSHI, Dallas, TX (US); Sylvester ANKAMAH-KUSI, McKinney, TX (US); Rajen Manicon MURUGAN, Dallas, TX (US); Karan BHATIA, Plano, TX (US); Moh VATANKHAH VARNOOSFADERANI, Dallas, TX (US); Jie CHEN, Plano, TX (US); Chun Ping LO, Allen, TX (US)

(21) Appl. No.: 19/067,017

(22) Filed: Feb. 28, 2025

(51) Int. Cl. H01L 23/66; H01L 23/31; H01L 23/498

(52) U.S. Cl. CPC H10W 44/20; H10W 70/65; H10W 70/685; H10W 44/223; H10W 74/111

(57) ABSTRACT

In examples, semiconductor package substrates include Marchand baluns. The baluns include multiple, open curve-shaped metal layers in the substrates.

### BACKGROUND

A balun is a type of transformer that is used to match the impedance of an unbalanced signal, such as a coaxial cable, to the impedance of a balanced signal, such as a twisted pair of wires. Marchand baluns, commonly used in antennas, amplifiers, and mixers, are a type of balun used in radio frequency (RF) circuits to convert between unbalanced and balanced signals. A Marchand balun uses a transmission line to create a phase shift between the input and output signals, which allows for the conversion from unbalanced to balanced signals. The transmission lines are quarter-wavelength or half-wavelength long, depending on the frequency of the signal being transmitted. The Marchand balun can also be used in reverse to convert from balanced to unbalanced signals. The Marchand balun provides good isolation between the input and output signals, which reduces interference and signal loss. Additionally, it can operate over a wide frequency range and can handle high power levels.

### SUMMARY

In examples, a semiconductor package includes a mold compound layer and a substrate layer contacting the mold compound layer. The substrate layer comprises a first copper layer forming a ground plane, with a second copper layer closer to the mold compound layer than the first copper layer, and with the second copper layer including a first end and a second end opposing the first end. A body of the second copper layer is between the first and second ends and has an open curve shape in a top view and a first width in the top view. The package includes a third copper layer closer to the mold compound layer than the second copper layer, the third copper layer including a third end and a fourth end opposing the third end, and a body of the third copper layer between the third and fourth ends having the open curve shape in the top view and a second width greater than the first width in the top view. The second and third copper layers form a Marchand balun. The third and fourth ends extend away from the first and second ends in the top view. The package includes a first metal contact coupled to the first end and having a surface that is approximately flush with a surface of the semiconductor package. The package includes a second metal contact coupled to the second end and having a surface that is approximately flush with the surface of the semiconductor package. The package includes a third metal contact coupled to the third end and having a surface that is approximately flush with the surface of the semiconductor package. The package includes a fourth metal contact coupled to the body of the second copper layer and having a surface that is approximately flush with the surface of the semiconductor package. The package includes a set of solder bumps contacting the first, second, third, and fourth metal contacts.

In examples, a method for manufacturing a semiconductor package includes depositing first and second metal seed layers on first and second opposing sides of a carrier, respectively; patterning first and second photoresist layers on the first and second metal seed layers, respectively; plating first and second metal layers using the first and second metal seed layers and the first and second photoresist layers, respectively, the first and second metal layers forming ground planes; and removing the first and second photoresist layers and portions of the first and second metal seed layers. The method includes applying first and second dielectric layers on the first and second metal layers, respectively; drilling first and second via holes in the first and second dielectric layers, respectively; and depositing third and fourth metal seed layers on the first and second dielectric layers, respectively, including inside the first and second via holes, respectively. The method includes patterning third and fourth photoresist layers on the third and fourth metal seed layers, respectively; plating first and second vias in the first and second via holes using the third and fourth metal seed layers, respectively; and plating third and fourth metal layers using the third and fourth metal seed layers and the third and fourth photoresist layers, respectively. The third metal layer includes a first end and a second end opposing the first end, the fourth metal layer includes a third end and a fourth end opposing the third end, a body of the third metal layer between the first and second ends having an open curve shape and a first width, and a body of the fourth metal layer between the third and fourth ends having the open curve shape and a second width. The third and fourth metal layers contact the first and second vias, respectively. The method includes removing the third and fourth photoresist layers and portions of the third and fourth metal seed layers; applying third and fourth dielectric layers to the third and fourth metal layers, respectively; drilling third and fourth via holes in the third and fourth dielectric layers, respectively; depositing fifth and sixth metal seed layers on the third and fourth dielectric layers, respectively, including inside the third and fourth via holes, respectively; patterning fifth and sixth photoresist layers on the fifth and sixth metal seed layers, respectively; plating third and fourth vias in the third and fourth via holes using the fifth and sixth metal seed layers, respectively; and plating fifth and sixth metal layers using the fifth and sixth metal seed layers and the fifth and sixth photoresist layers, respectively. The fifth metal layer includes a fifth end and a sixth end opposing the fifth end, a body of the fifth metal layer between the fifth and sixth ends having the open curve shape and a third width greater than the first width. The third and fifth metal layers form a first Marchand balun. The sixth metal layer includes a seventh end and an eighth end opposing the seventh end, a body of the sixth metal layer between the seventh and eighth ends having the open curve shape and a fourth width greater than the second width. The fourth and sixth metal layers form a second Marchand balun, the fifth and sixth metal layers contacting the third and fourth vias, respectively. The method includes removing the fifth and sixth photoresist layers and portions of the fifth and sixth metal seed layers; removing the carrier; applying a first solder mask to the first metal layer and a second solder mask to the fifth metal layer; and applying a mold compound to the second solder mask.

### BRIEF DESCRIPTION OF THE DRAWINGS

FIG. 1 is a circuit schematic diagram of a Marchand balun, in accordance with various examples.

FIGS. 2A, 2B, 2C, and 2D are top-down, profile, profile, and perspective views of a portion of a Marchand balun in a package substrate, in accordance with various examples.

FIGS. 3A, 3B, 3C, and 3D are top-down, profile, profile, and perspective views of a portion of a Marchand balun in a package substrate, in accordance with various examples.

FIGS. 4A, 4B, 4C, and 4D are cross-sectional, top-down, perspective, and conceptual views of a semiconductor package including a package substrate having a Marchand balun, in accordance with various examples.

FIGS. 5A, 5B, 5C, 5D, and 5E are top-down, profile, profile, perspective, and bottom-up views of a semiconductor package including a package substrate having a Marchand balun, in accordance with various examples.

FIGS. 6A, 6B, and 6C are cross-sectional, top-down, and perspective views of a semiconductor package including a package substrate having a Marchand balun, in accordance with various examples.

FIGS. 7A and 7B depict a flow diagram of a method for manufacturing a semiconductor package including a package substrate having a Marchand balun, in accordance with various examples.

FIG. 8A1, 8A2, 8B1, 8B2, 8C1, 8C2, 8D1, 8D2, 8E1, 8E2, 8F1, 8F2, 8G1, 8G2, 8H1, 8H2, 8I1, 8I2, 8J1, 8J2, 8K1, 8K2, 8L1, 8L2, 8M1, 8M2, 8N1, 8N2, 8O1, 8O2, 8P1, 8P2, 8Q1, 8Q2, 8R1, 8R2, 8S1, 8S2, 8T1, 8T2, 8U1, 8U2, 8V1, 8V2, 8W1, 8W2, 8X1, 8X2, 8Y1, and 8Y2 are a process flow for manufacturing a semiconductor package including a package substrate having a Marchand balun, in accordance with various examples.

FIGS. 9, 10, 11, and 12 are graphs depicting operational behavior of a semiconductor package including a package substrate having a Marchand balun, in accordance with various examples.

FIG. 13 is a block diagram of an electronic device including a semiconductor package that includes a substrate having a Marchand balun, in accordance with various examples.

### DETAILED DESCRIPTION

Although Marchand baluns provide various benefits, the design and implementation of a Marchand balun can be complex, and it requires careful attention to the physical dimensions and electrical properties of the transmission line. In addition, although baluns are passive devices, they tend to occupy large amounts of space on the circuitry-containing, active (i.e., device) surfaces of semiconductor dies, which is a highly inefficient use of valuable active surface space. Space-conserving efforts to relocate baluns from dies to other areas within the semiconductor package, such as cored substrates coupled to the dies, have produced mixed results, as such cored substrates tend to be expensive and have prohibitively challenging design rules.

This disclosure describes various examples of a semiconductor package comprising a Marchand balun in a coreless package substrate (e.g., embedded trace substrate (ETS)). In examples, a semiconductor package includes a mold compound layer and a substrate layer physically contacting the mold compound layer. The substrate layer includes a first copper layer forming a ground plane and a second copper layer closer to the mold compound layer than the first copper layer. The second copper layer includes a first end and a second end opposing the first end. A body of the second copper layer is between the first and second ends and has an open curve shape and a first width. The substrate layer includes a third copper layer closer to the mold compound layer than the second copper layer. The third copper layer includes a third end and a fourth end opposing the third end. A body of the third copper layer is between the third and fourth ends and has the open curve shape and a second width greater than the first width. The second and third copper layers form a Marchand balun. The package also includes a first metal contact coupled to the first end, a second metal contact coupled to the second end, a third metal contact coupled to the third end, and a fourth metal contact coupled to the body of the second copper layer.

By positioning the Marchand balun in a coreless substrate using the unique balun structures described herein, the technical challenges described above (specifically, inefficiencies in package space usage and design rule challenges associated with cored substrates) are mitigated. The examples described herein also provide numerous other advantages over prior solutions. For example, because coreless substrates are less expensive than cored substrates, and because the examples described herein occupy less space than the space occupied in cored substrates (e.g., three substrate layers as opposed to six or more substrate layers in cored substrates), costs are mitigated. In addition, due to the more permissive design rules of coreless substrates (e.g., coreless embedded trace substrate (ETS)), the horizontal area occupied by the metal layers in the coreless substrate is reduced relative to the horizontal area occupied by metal layers in cored substrates, thereby reducing costs. In the examples described herein, experimental data show that wider bandwidths (e.g., 9 GHz) are achieved relative to those achieved in cored substrates (e.g., 5.35 GHz). Further still, amplitude and phase imbalances and common mode rejection ratio (CMRR) performance is superior to that in cored substrates and a center tap connecting one of the metal layers in the coreless substrate to ground can be tuned to mitigate such imbalances and CMRR inadequacies.

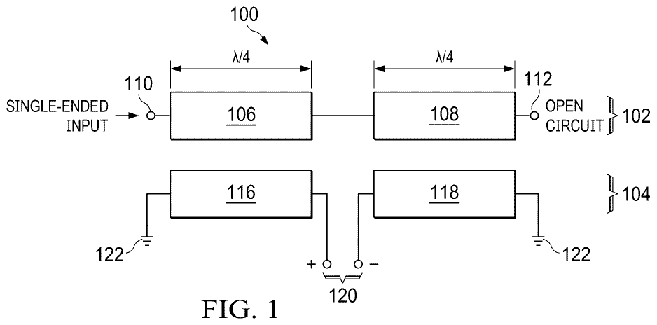

FIG. 1 is a circuit schematic diagram of a Marchand balun, in accordance with various examples. Specifically, FIG. 1 shows a Marchand balun 100 including a metal layer 102 and a metal layer 104. The metal layer 102 includes a serpentine portion 106 and a serpentine portion 108 coupled to the serpentine portion 106. For example, each of the serpentine portions 106, 108 may include metal segments arranged in a serpentine configuration, e.g., parallel and/or perpendicular to each other, as described below. The metal layer 102 includes a single-ended input/output (I/O) 110 and an open circuit end 112. The metal layer 104 includes a serpentine portion 116 and a serpentine portion 118. Each of the serpentine portions 116, 118 may include metal segments arranged in a serpentine configuration, e.g., parallel and/or perpendicular to each other, as described below. The metal layer 104 includes a differential I/O 120, one terminal of which extends from the serpentine portion 116, and the other terminal of which extends from the serpentine portion 118. Each of the serpentine portions 116, 118 couples to a ground terminal 122. In an example operation, an input signal provided at single-ended I/O 110 is converted into a differential signal, with a phase difference of 180 degrees, at differential I/O 120. Similarly, an input signal provided at differential I/O 120 may be converted to a single output signal at single-ended I/O 110.

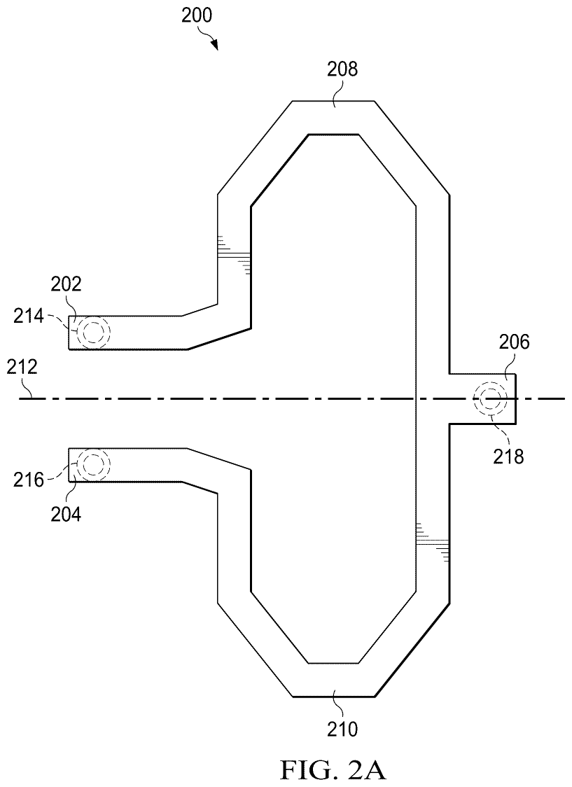

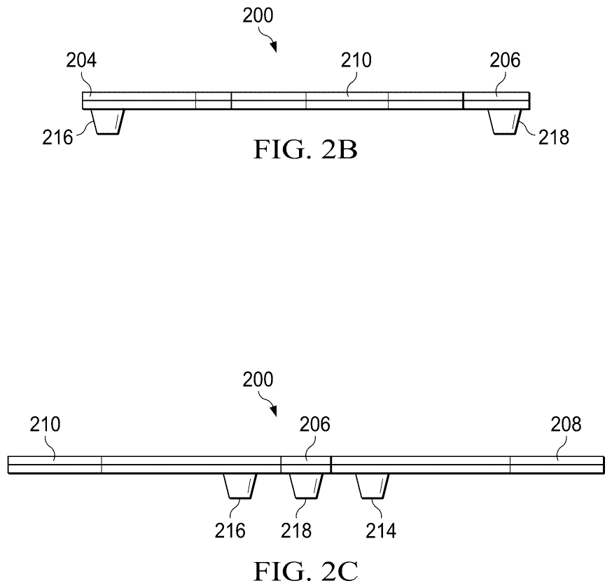

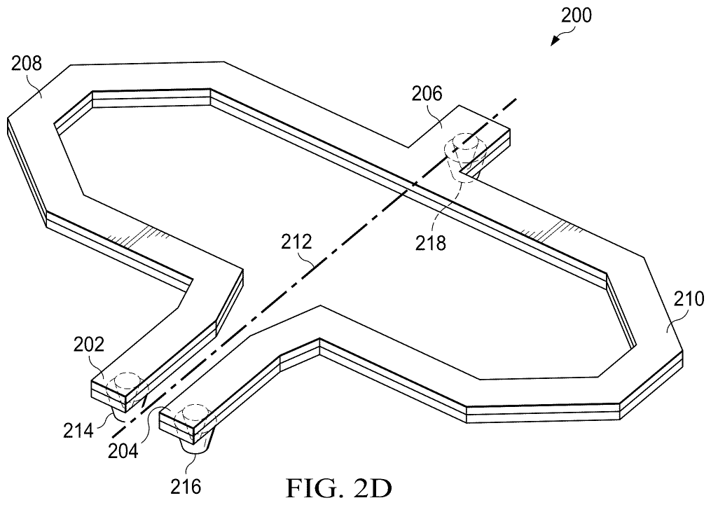

FIGS. 2A, 2B, 2C, and 2D are top-down, profile, profile, and perspective views of a portion of a Marchand balun in a package substrate, in accordance with various examples. In particular, FIGS. 2A-2D depict various views of a metal layer 200, which is an example of the metal layer 104 of FIG. 1. The metal layer 200 includes a first end 202, a second end 204 opposite the first end 202, and a center tap 206 in between the first and second ends 202 and 204. As shown, the metal layer 200 has an open curve shape (i.e., a shape formed by a continuous line that has two distinct endpoints and that does not enclose an area within itself, such as a curve where the starting point and endpoint are not connected to each other) in a top view, with the specific shape of the metal layer 200 varying depending on the application. In examples, the first and second ends 202, 204 face the same direction in the top view, and in other examples, the first and second ends 202, 204 face different directions in the top view. In examples, the center tap 206 faces a direction opposite that faced by the first and second ends 202, 204 in the top view. The metal layer 200 includes a first arm 208 that extends between the first end 202 and the center tap 206. The metal layer 200 also includes a second arm 210 that extends between the second end 204 and the center tap 206. The first arm 208 extends away from a centerline 212 that extends through a center of the center tap 206 and through a midpoint equidistant between the first and second ends 202, 204, in the top view. The first arm 208 subsequently turns toward the first end 202 in the top view (e.g., approximately 45 degrees), then turns again toward the first end 202 in the top view (e.g., approximately 45 degrees), such that the first arm 208 is extending approximately parallel to the first end 202. The first arm 208 then turns again toward the first end 202 in the top view (e.g., approximately 45 degrees), and then turns once more in the top view (e.g., approximately 45 degrees), such that the first arm 208 extends approximately perpendicular to the first end 202. The first arm 208 then turns to meet the first end 202 in the manner shown. The second arm 210 is the mirror image of the first arm 208 in the top view, as shown. The center tap 206 is referred to as the “center” tap because the center tap 206 is equidistant, along the contours of the first and second arms 208, 210, from the first and second ends 202, 204, respectively.

A via 214 is coupled to the first end 202 and extends in the vertical direction away from the first end 202. A via 216 is coupled to the second end 204 and extends in the vertical direction away from the second end 204. A via 218 is coupled to the center tap 206 and extends in the vertical direction away from the center tap 206. The via 218 may be coupled to the center tap 206 along the centerline 212, equidistant from the first and second ends 202, 204.

The first end 202 (and, by extension, the via 214) is configured to operate as a first signal terminal. The second end 204 (and, by extension, the via 216) is configured to operate as a second signal terminal. The first and second ends 202, 204 are configured to receive a differential signal into the metal layer 200 (as input), or to provide a differential signal out of the metal layer 200 (as output).

The thickness of the metal layer 200 ranges from 12 microns to 16 microns, with a thickness below this range being disadvantageous because of unacceptably poor mechanical rigidity and the possibility of warpage, and with a thickness above this range being disadvantageous because of manufacturability limitations. The width of the metal layer 200 in the top view is determined by the transmission line impedance and the frequency of operation.

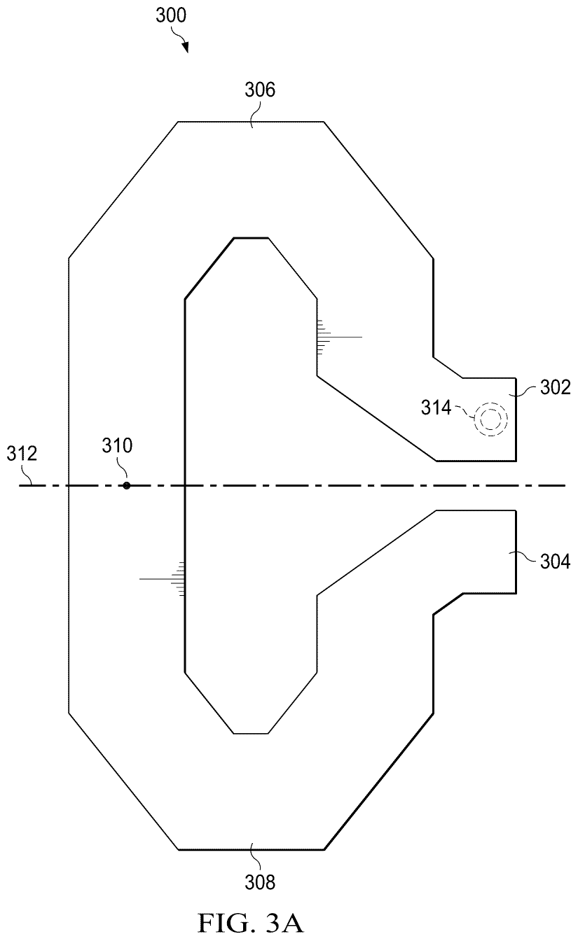

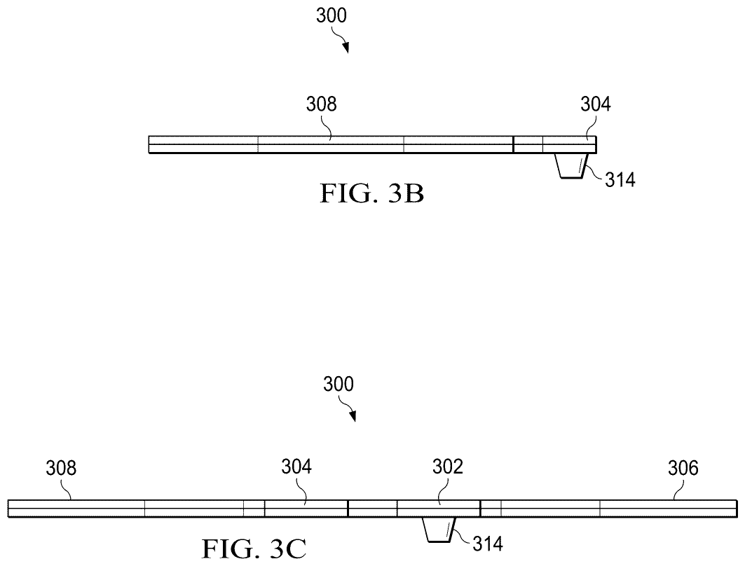

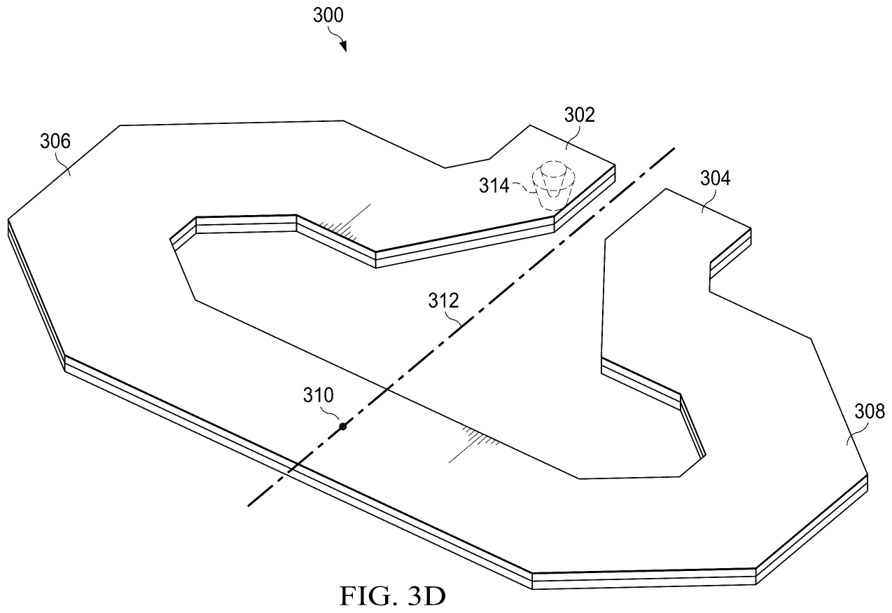

FIGS. 3A, 3B, 3C, and 3D are top-down, profile, profile, and perspective views of a portion of a Marchand balun in a package substrate, in accordance with various examples. In particular, FIGS. 3A-3D depict various views of a metal layer 300, which is an example of the metal layer 102 of FIG. 1. The metal layer 300 includes a first end 302 and a second end 304 opposite the first end 302. As shown, the metal layer 300 has an open curve shape in a top view, with the specific shape of the metal layer 300 varying depending on the application. In examples, the first and second ends 302, 304 face the same direction in the top view, and in other examples, the first and second ends 302, 304 face different directions in the top view. In examples, the first and second ends 302, 304 face the opposite direction than (i.e., extend away from) the first and second ends 202, 204. The metal layer 300 includes a first arm 306 that extends between the first end 302 and a midpoint 310. The metal layer 300 also includes a second arm 308 that extends between the second end 304 and the midpoint 310. The first arm 306 extends away from a centerline 312 that extends through the midpoint 310 and a midpoint equidistant between the first and second ends 302, 304, in the top view. The first arm 306 subsequently turns toward the midpoint 310 in the top view (e.g., approximately 45 degrees), then turns again toward the midpoint 310 in the top view (e.g., approximately 45 degrees), such that the first arm 306 is extending approximately parallel to the first end 302. The first arm 306 then turns again toward the midpoint 310 in the top view (e.g., approximately 45 degrees), and then turns once more in the top view (e.g., approximately 45 degrees), such that the first arm 306 extends approximately perpendicular to the first end 302. The second arm 308 is the mirror image of the first arm 306 in the top view, as shown.

A via 314 is coupled to the first end 302 and extends in the vertical direction away from the first end 302. No via is coupled to the second end 304.

The first end 302 (and, by extension, the via 314) is configured to operate as a first signal terminal. The second end 304 is configured to operate as an open circuit. The first end 302 is configured to receive a single-ended signal into the metal layer 300 (as input), or to provide a single-ended signal out of the metal layer 300 (as output).

The thickness of the metal layer 300 ranges from 12 microns to 16 microns, with a thickness below this range being disadvantageous because of unacceptably poor mechanical rigidity and the possibility of warpage, and with a thickness above this range being disadvantageous because of manufacturability limitations. The width of the metal layer 300 in the top view is determined by the transmission line impedance and the frequency of operation. The metal layer 300 is wider than the metal layer 200, as shown. In at least some examples, the metal layers 200, 300 overlap in the top view, meaning that along the majorities of the lengths of the metal layers 200, 300, a vertical line extends through both of the metal layers 200, 300. This overlap between the metal layers 200, 300 in the top view is useful because it couples radio frequency (RF) energy (i.e., RF signals) between the metal layers 200 and 300. This is critical for the operation of this type of a broadside coupled Marchand balun. In other examples, the majorities of the lengths of the metal layers 200, 300 do not overlap in the top view.

The first and second ends 202, 204 and the first end 302, as well as the center tap 206 (FIGS. 2A-2D and 3A-3D) are spatially positioned such that the respective vias 214, 216, 218, and 314 extend vertically without physically contacting the other metal layer. Specifically, the vias 214, 216, and 218 do not physically contact the metal layer 300, and the via 314 does not physically contact the metal layer 200. Similarly, the metal layers 200, 300 do not physically contact each other.

The metal layers 200, 300 are symmetrical in multiple aspects. For example, the first arm 208 and second arm 210 have equal lengths and are mirror images of each other. Similarly, the first arm 306 and the second arm 308 have equal lengths and are mirror images of each other. The metal layers 200, 300 have similar shapes and may be aligned as described above. Such symmetrical features facilitate the production of output signals that have the same magnitude but opposite phase (i.e., phases that are 180 degrees apart), thereby preventing distortion in differential signaling. Such symmetry also facilitates proper impedance matching, minimization of common-mode noise, and the prevention of unequal coupling and signal distortion.

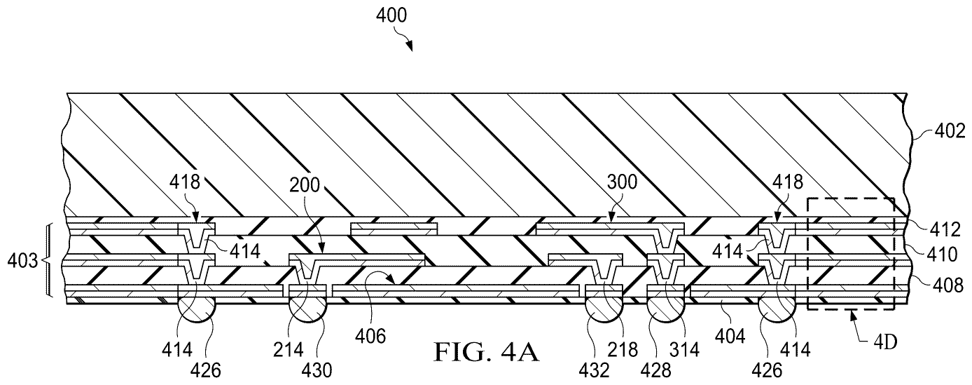

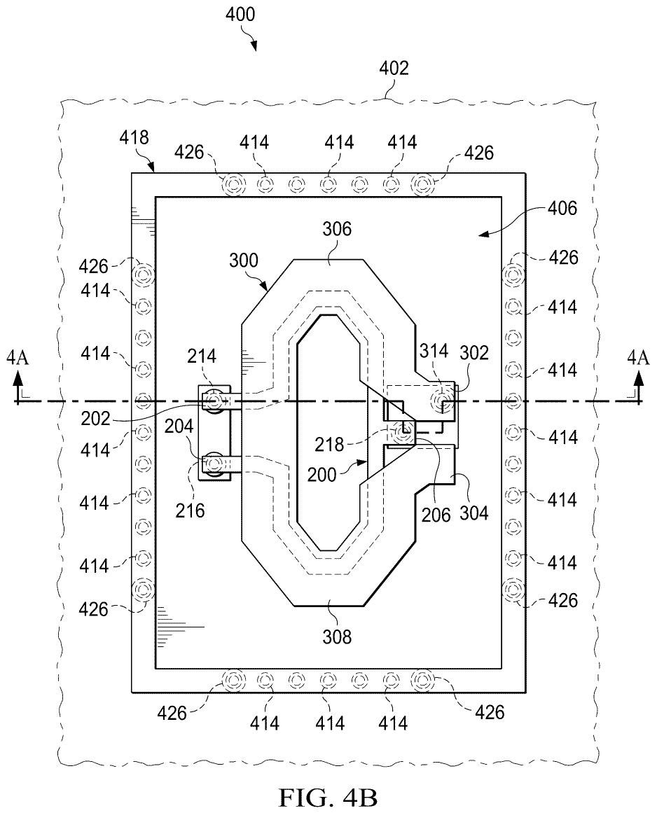

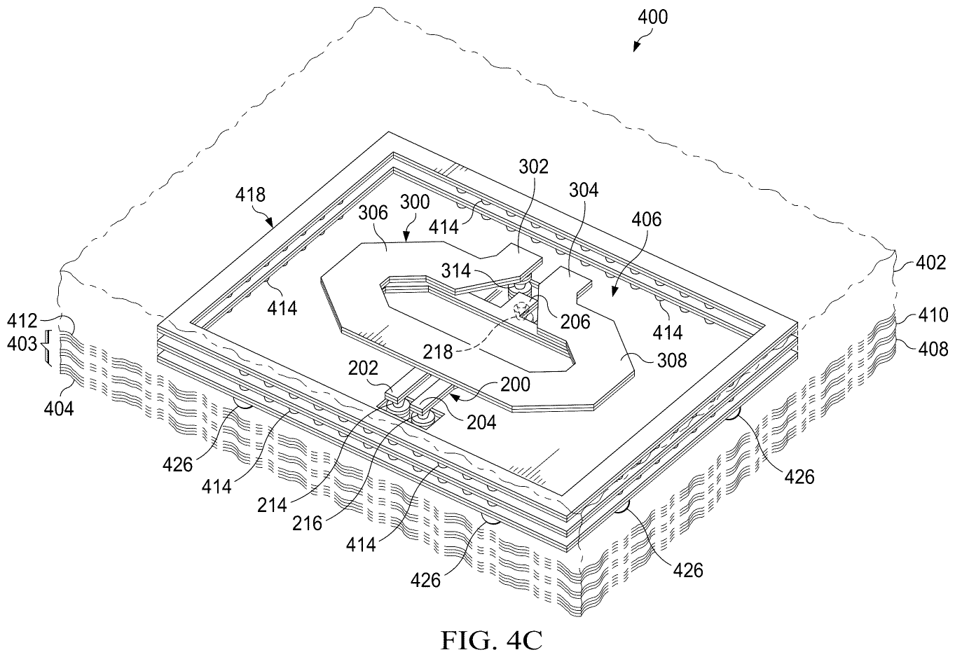

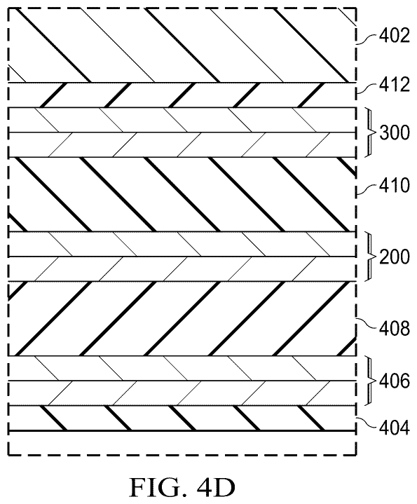

Together, the metal layers 200, 300 form a Marchand balun. Specifically, the metal layer 200 corresponds to the metal layer 104 (FIG. 1), and the metal layer 300 corresponds to the metal layer 102 (FIG. 1). Such a Marchand balun may be included in the substrate of a semiconductor package, providing the various technical advantages described above. FIGS. 4A, 4B, 4C, and 4D are cross-sectional, top-down, perspective, and conceptual views of a semiconductor package 400 including a package substrate having a Marchand balun, in accordance with various examples. In particular, the semiconductor package 400 includes a mold compound 402 and a package substrate 403 coupled to the mold compound 402. The package substrate 403 includes a solder mask layer 404, a metal layer 406 physically contacting a top surface of the solder mask layer 404, a dielectric layer 408 (e.g., pre-preg) physically contacting a top surface of the metal layer 406, the metal layer 200 (e.g., FIG. 2) physically contacting a top surface of the dielectric layer 408, a dielectric layer 410 (e.g., pre-preg) physically contacting a top surface of the metal layer 200, the metal layer 300 (e.g., FIG. 3) physically contacting a top surface of the dielectric layer 410, and a solder mask layer 412 physically contacting a top surface of the metal layer 300.

In examples, the metal layer 406 is a ground plane, meaning that the metal layer 406 is a flat sheet of metal coupled to a ground potential. Although the metal layer 406 is a flat sheet of metal, one or more members (e.g., vias) may extend through the horizontal plane in which the metal layer 406 is present, as described herein.

The dielectric layer 408 has a thickness ranging from 18 microns to 45 microns, with a thickness below this range being disadvantageous because of unacceptably poor mechanical rigidity, and with a thickness above this range being disadvantageous because of reduced RF signal coupling between signal carrying metal layers 200 and 300. The dielectric layer 408 may include pre-preg or any other suitable material, such as AJINOMOTO® build-up film (ABF). The description that applies to the dielectric layer 408 also applies to the dielectric layer 410.

Portions of the metal layer 200, such as the first and second arms 208, 210, are in the horizontal plane above the dielectric layer 408, but portions of the metal layer 200, such as the vias 214, 216, and 218, extend through the horizontal planes of the dielectric layer 408 (e.g., pre-preg) and the metal layer 406 to couple to solder bumps in the solder mask layer 404 (described below). The metal layer 200 may be manufactured with suitable photolithography and plating techniques, examples of which are described herein.

Portions of the metal layer 300, such as the first and second arms 306, 308, are in the horizontal plane above the dielectric layer 410, but portions of the metal layer 300, such as the via 314, extend through the horizontal planes of the dielectric layer 410 (e.g., pre-preg), the metal layer 200, the dielectric layer 408, and the metal layer 406 to couple to solder bumps in the solder mask layer 404 (described below). The metal layer 300 may be manufactured with suitable photolithography and plating techniques, examples of which are described herein.

The solder mask layers 404 and 412 have thicknesses ranging from 10 microns to 15 microns, with a thickness outside this range violating design manufacturing rules.

The various vias described herein (e.g., vias 214, 216, 218, 314) may have any suitable size and shape. In examples, the package substrate 403 of the semiconductor package 400 is an embedded trace substrate (ETS) in which bespoke metal layers are formed by photolithography and plating techniques and are separated from each other by dielectric layers through which vias may extend. In ETSs, the vias may have a trapezoidal appearance in the profile cross-sectional view, and circular in a horizontal cross-sectional view. In ETSs, the dielectric layers may include pre-preg. In ETSs, solder masks (e.g., solder mask layers 404, 412) are included on the top and bottom surfaces of the substrate. ETSs are coreless. In ETSs, a minimum metal trace width (in the horizontal direction) is 8 microns. In ETSs, the horizontal distance between adjacent traces in the top view is 8 microns. In ETSs, the minimum metal layer thickness in the vertical direction is 12 microns. In ETSs, the minimum dielectric thickness is 18 microns.

In examples, the package substrate 403 is a routable lead frame substrate (RLFS) formed by an iterative process in which a metal layer is deposited, a dielectric is applied on the metal layer, the dielectric layer is grinded to thin the dielectric layer and to expose the metal layer, and then the process is repeated. In RLFSs, the vias may have a cylindrical appearance in the profile cross-sectional view. In RLFSs, the dielectric layers may include build-up films, such as AJINOMOTO® build-up film (ABF), and are thicker than ETS pre-preg layers. In RLFSs, solder masks may be omitted. RLFSs are coreless. In RLFSs, a minimum metal trace width (in the horizontal direction) is 30 microns. In RLFSs, the horizontal distance between adjacent traces in the top view is 40 microns. In RLFSs, the minimum metal layer thickness in the vertical direction is 30 microns. In RLFSs, the minimum dielectric thickness is 30 microns. Other types of substrates and manufacturing techniques thereof are contemplated and included in the scope of this disclosure.

The package substrate 403 includes a ground wall 418 coupled to and extending vertically upward from the metal layer 406, which forms the aforementioned ground plane. The ground wall 418 has four segments intersecting at right angles in the top view and surrounding the Marchand balun that is present in the package substrate 403 (i.e., the specific structures depicted in FIGS. 2A-2D and 3A-3D). In examples, the ground wall 418 includes a metal segment in each of the metal layers 406, 200, and 300 coupled to each other by multiple vias 414, and thus the ground wall 418 may also be referred to herein as a metal wall. The ground wall 418 extends from the bottom-most metal layer in the package substrate 403 (e.g., the metal layer 406) to the top-most metal layer in the package substrate 403 (e.g., the metal layer 300). The thickness of the ground wall 418 in the horizontal direction is consistent with the thicknesses of the metal traces in the metal layers 200 and 300 as described herein. The description provided above for the remaining vias in the package substrate 403 also applies to the vias 414.

Solder bumps 426 couple to the ground wall 418. A solder bump 428 couples to the metal layer 300, and specifically to the first end 302, by way of the via 314. A solder bump 430 couples to the metal layer 200, and specifically to the first end 202, by way of the via 214. A solder bump (not expressly shown) couples to the metal layer 200, and specifically to the second end 204, by way of the via 216. A solder bump 432 couples to the metal layer 200, and specifically to the center tap 206, by way of the via 218.

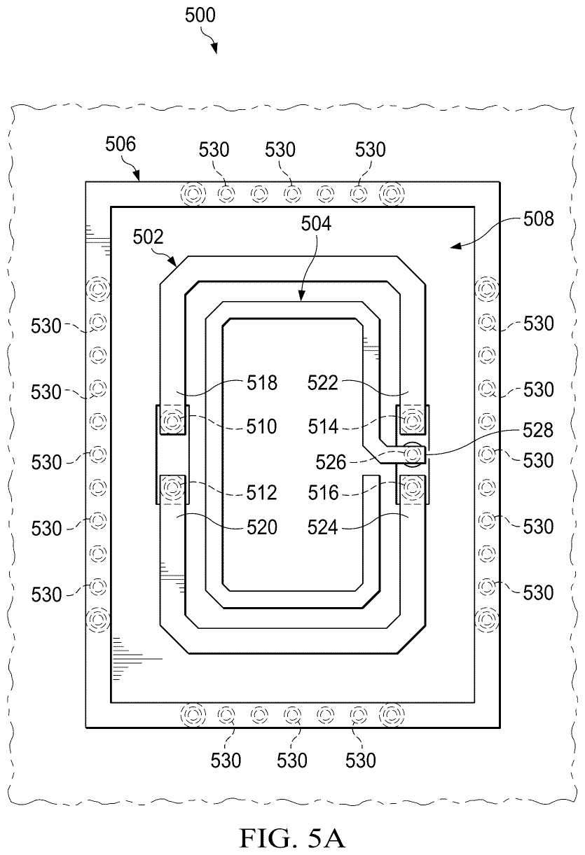

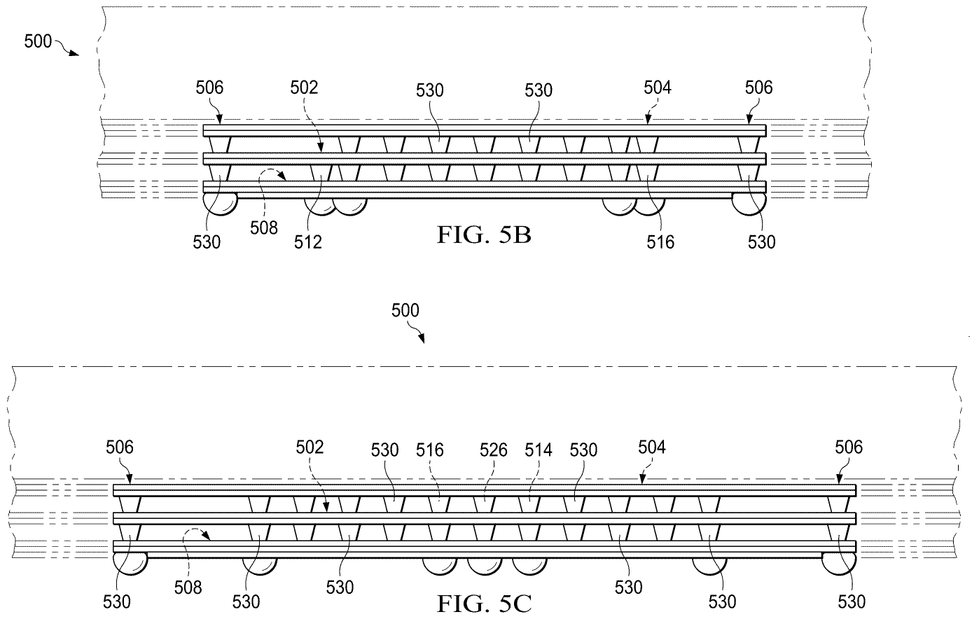

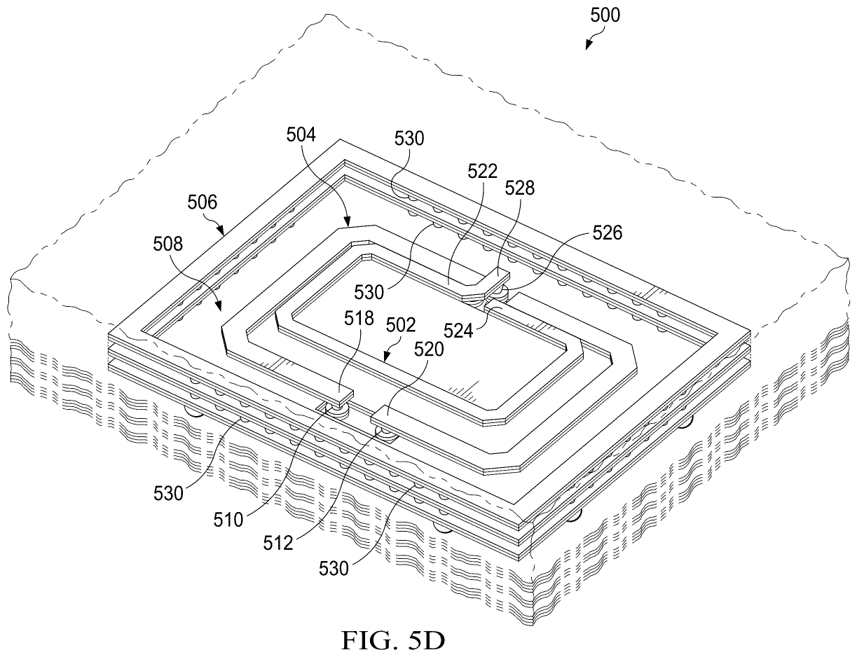

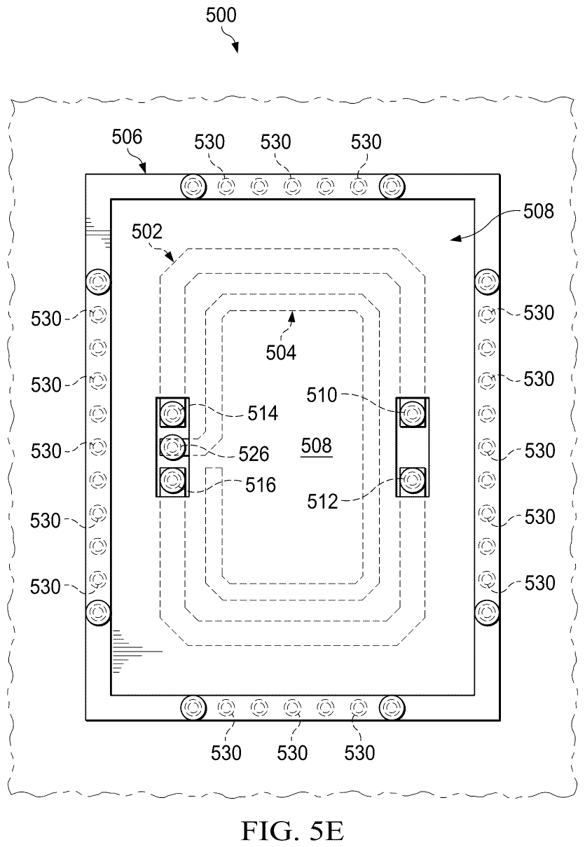

In at least some of the examples described above, the metal layer 200 is a single, continuous piece of metal. However, in some examples, the metal layer 200 may include multiple pieces of metal. For example, the metal layer 200 may be divided at the center tap 206. FIGS. 5A, 5B, 5C, 5D, and 5E are top-down, profile, profile, perspective, and bottom-up views of a semiconductor package including a package substrate having a Marchand balun, in accordance with various examples. More specifically, FIGS. 5A-5E depict a semiconductor package 500 that includes a metal layer 502 that is similar to the metal layer 200, a metal layer 504 that is similar to the metal layer 300, a ground wall 506 that is similar to the ground wall 418, and a metal layer 508 that is similar to the metal layer 406 (i.e., a ground plane). The semiconductor package 500 also includes vias 510, 512, 514, and 516 that provide an electrical pathway from ends 518, 520, 522, and 524 of the metal layer 502, respectively, to the bottom of the semiconductor package 500, where these vias may couple to solder bumps. The ends 522, 524, which are bridged by the center tap 206 in the example of FIGS. 2A-2D, are separated by dielectric material positioned in between the ends 522, 524. The semiconductor package 500 further includes a via 526 that provides an electrical pathway from end 528 of the metal layer 504 to the bottom of the semiconductor package 500, where this via may couple to a solder bump. The semiconductor package 500 further includes multiple vias 530 that couple multiple layers of the ground wall 506 to each other and to the metal layer 508 (i.e., the ground plane), as well as to solder bumps at the bottom of the semiconductor package 500.

The semiconductor package 500 also includes various other components, such as multiple dielectric layers in between the metal layers 502, 504, and 508, multiple solder mask layers, solder bumps, a mold compound, etc., but these components are not expressly shown in FIGS. 5A-5E to facilitate a clear view of the components that are shown.

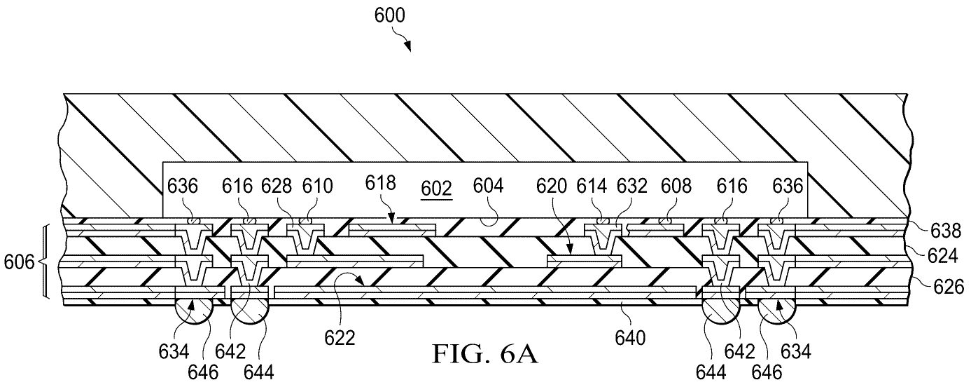

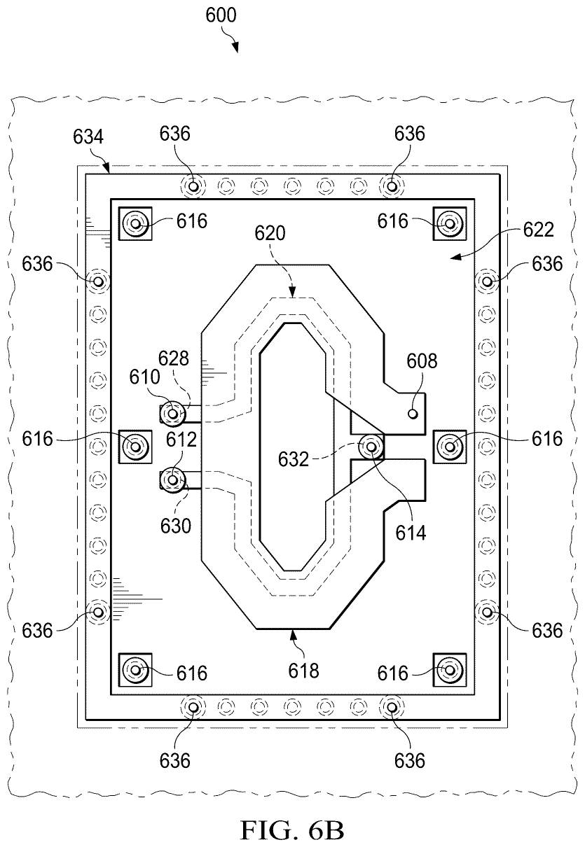

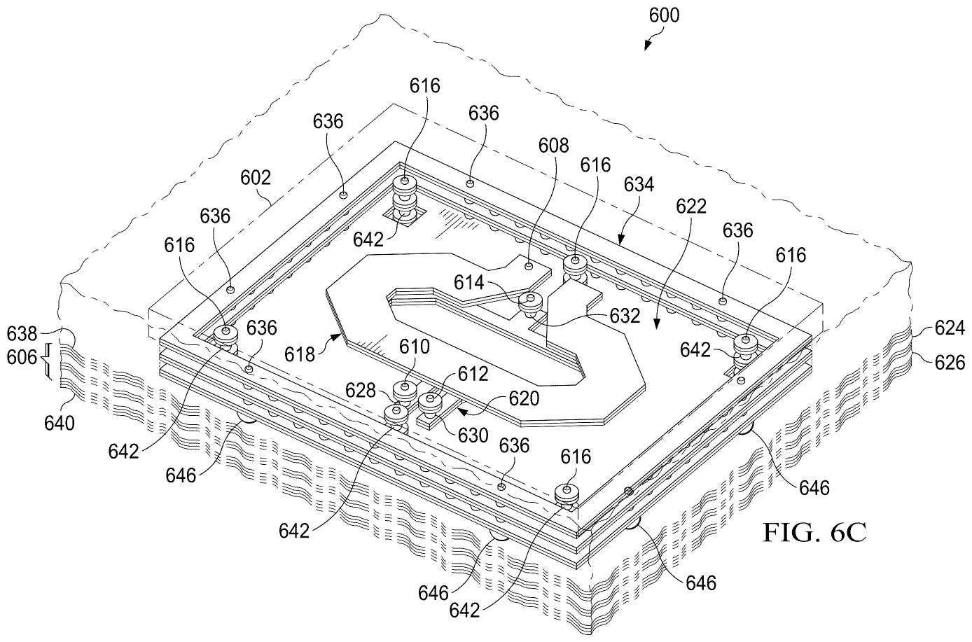

In the examples described above, the semiconductor package (e.g., semiconductor packages 400, 500) are standalone packages, meaning that they are to be coupled to printed circuit boards (PCBs) to which other components, such as controller circuitry, are also coupled. The controller circuitry communicates with the semiconductor package through the metal traces on the PCB. In this way, the controller circuitry accesses the functionality provided by the semiconductor package, e.g., the Marchand balun in the semiconductor packages 400, 500. However, in some examples, the semiconductor package includes both the Marchand balun and the controller circuitry, such as a semiconductor die including such controller circuitry. FIGS. 6A, 6B, and 6C are cross-sectional, top-down, and perspective views of a semiconductor package including a package substrate having a Marchand balun, in accordance with various examples. More specifically, FIGS. 6A-6C depict a semiconductor package 600 including a semiconductor die 602 having a device side 604 in which circuitry is formed. The semiconductor die 602 is oriented such that the device side 604 faces downward. The semiconductor package 600 includes a substrate 606 coupled to the device side 604 by multiple solder bumps 608, 610, 612, 614, and 616. The substrate 606 includes metal layers 618, 620, and 622, which are similar to the metal layers 300, 200, and 406 (FIGS. 4A-4D), respectively. Dielectric layer 624 is between the metal layers 618 and 620, and dielectric layer 626 is between metal layer 620 and 622. The dielectric layers 624, 626 may be pre-preg, ABF, etc.

The solder bump 608 couples the device side 604 to the metal layer 618. The solder bump 610 couples the device side 604 to a via 628, and the via 628 is coupled to the metal layer 620 (e.g., to a first end of the metal layer 620). The solder bump 612 couples the device side 604 to a via 630, and the via 630 is coupled to the metal layer 620 (e.g., to a second end of the metal layer 620 opposite the first end of the metal layer 620). The solder bump 614 couples the device side 604 to a via 632, and the via 632 is coupled to the metal layer 620 (e.g., to a center tap of the metal layer 620). In this way, the circuitry in the device side 604 of the semiconductor die 602 has electrical access to each functional node of each of the metal layers 618, 620.

The substrate 606 also includes a ground wall 634, which is similar to the ground wall 418 (FIGS. 4A-4D). The ground wall 418 surrounds the metal layers 618, 620 and the various vias coupled to the metal layers 618, 620. Solder bumps 636 couple the ground wall 634 to the device side 604. A solder mask layer 638 is between the substrate 606 and the device side 604, surrounding the various solder bumps between the substrate 606 and the device side 604. A solder mask layer 640 forms a bottom surface of the substrate 606.

The substrate 606 includes vias 642. Solder bumps 616 couple the device side 604 to the vias 642. The vias 642 extend through a thickness of the substrate 606 and couple to solder bumps 644. The ground wall 634 couples to multiple solder bumps 646. The solder mask layer 640 may surround the solder bumps 644, 646.

In operation, the circuitry on the semiconductor die 602 accesses and operates the Marchand balun, which is located in the substrate 606, through the solder bumps 608, 610, 612, and 614. The semiconductor die 602 accesses ground through solder bumps 636. The ground wall 634 couples to ground through the solder bumps 646, such as on a PCB. The circuitry on the semiconductor die 602 accesses metal traces on the PCB (and other components coupled to the PCB) through the solder bumps 616, the vias 642, and the solder bumps 644.

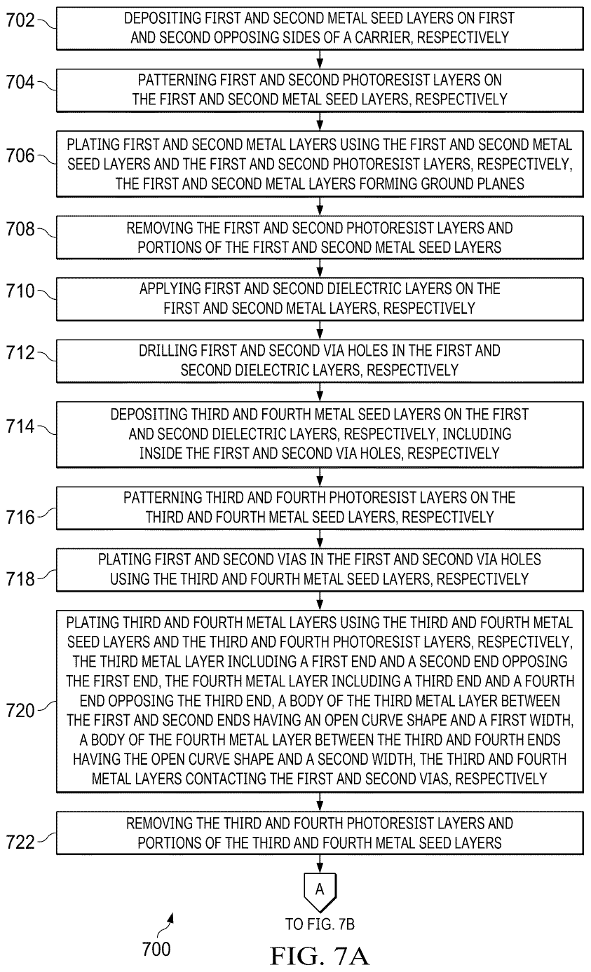

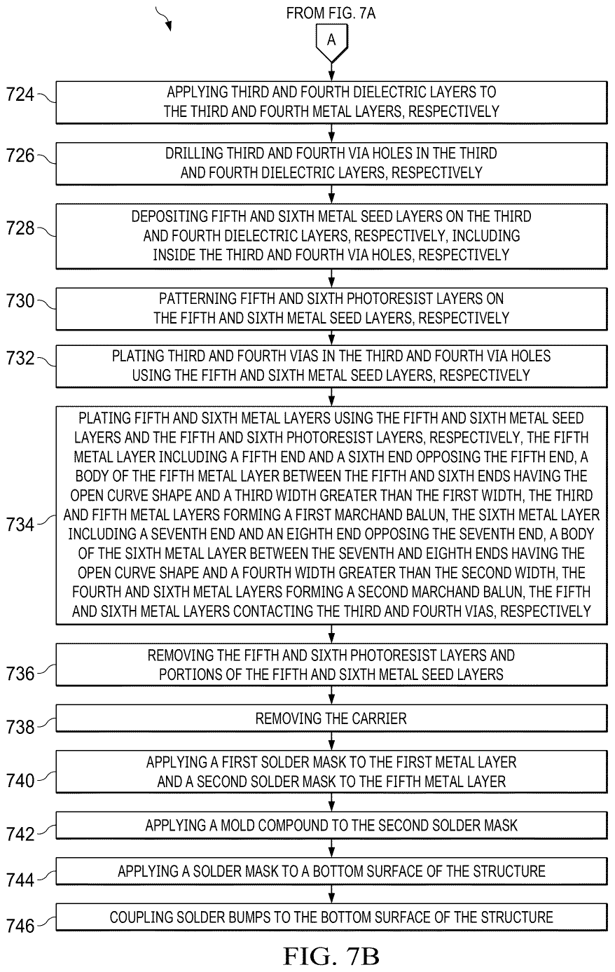

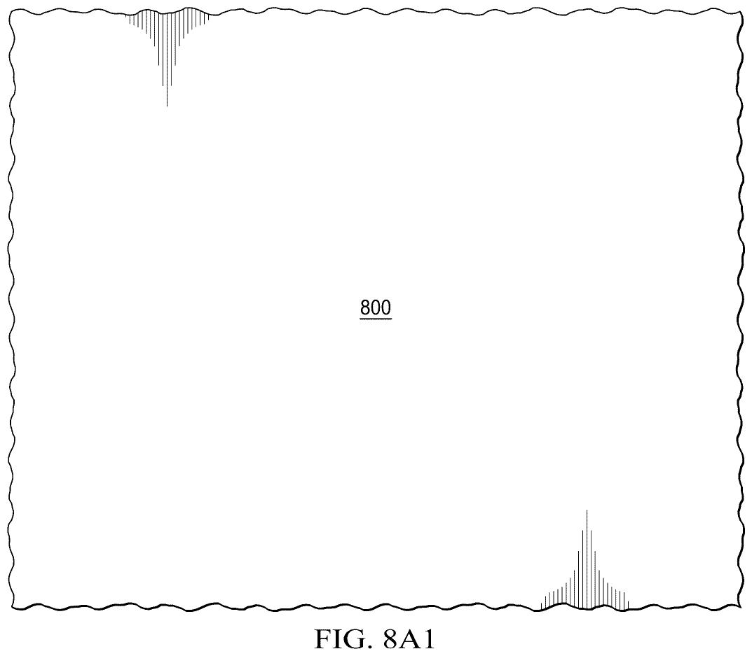

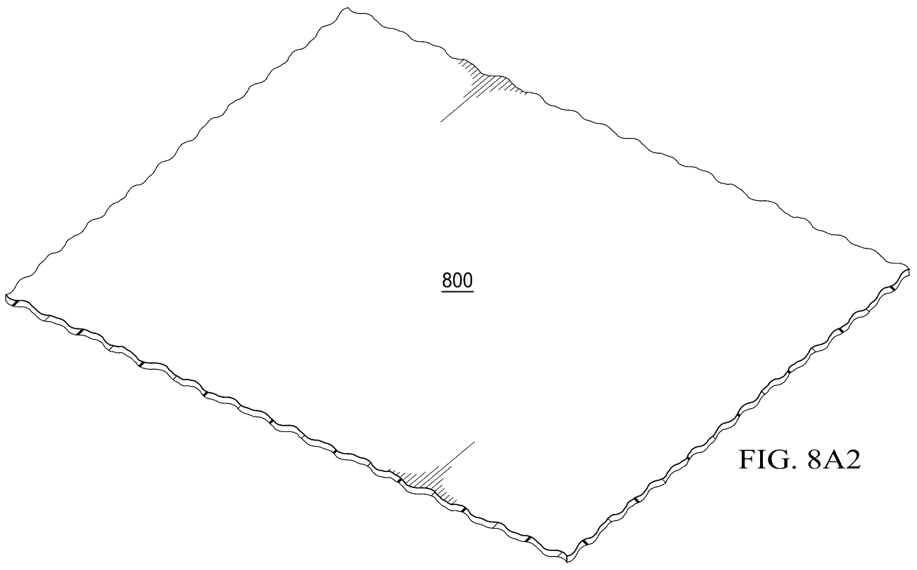

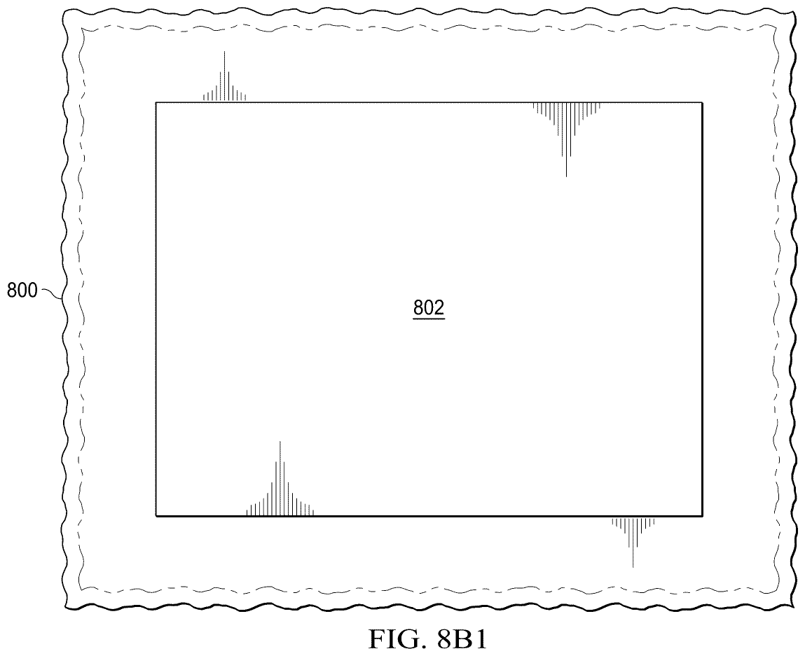

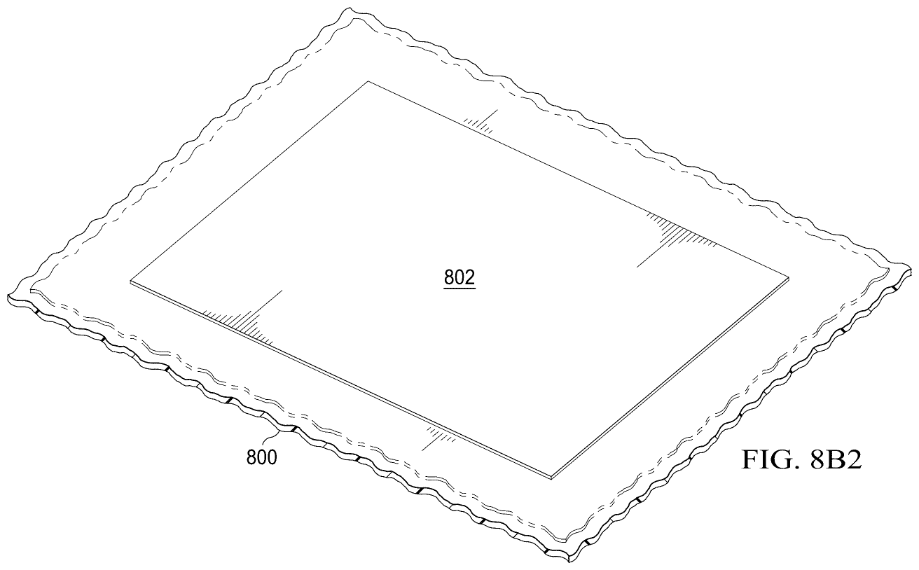

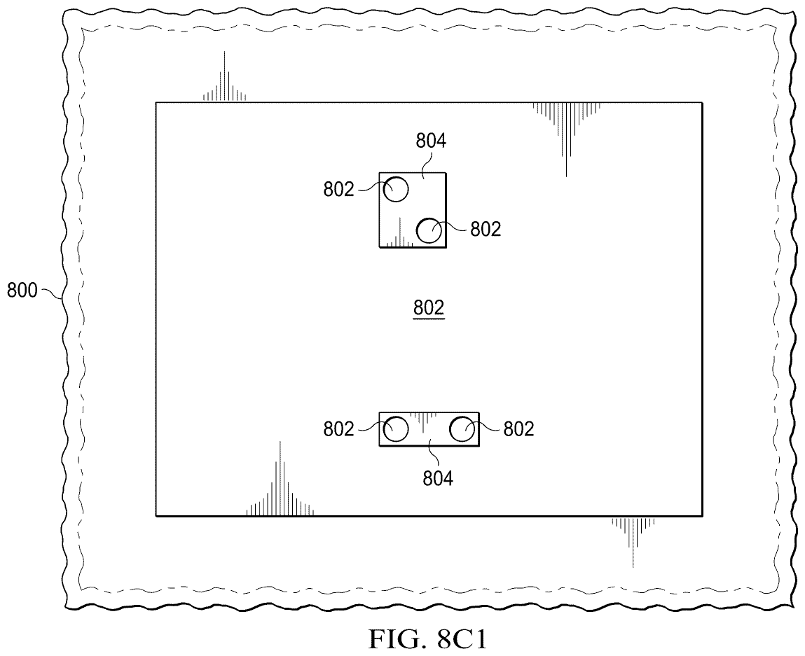

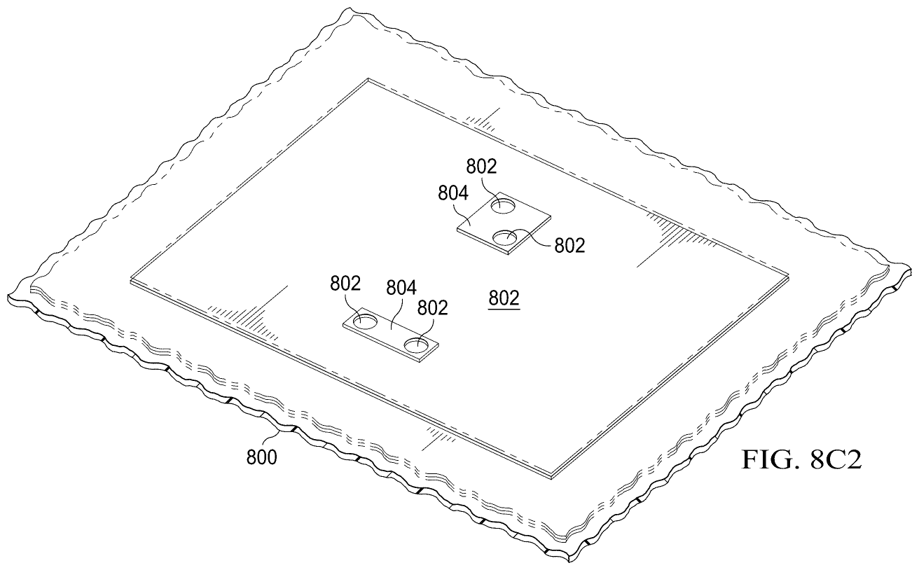

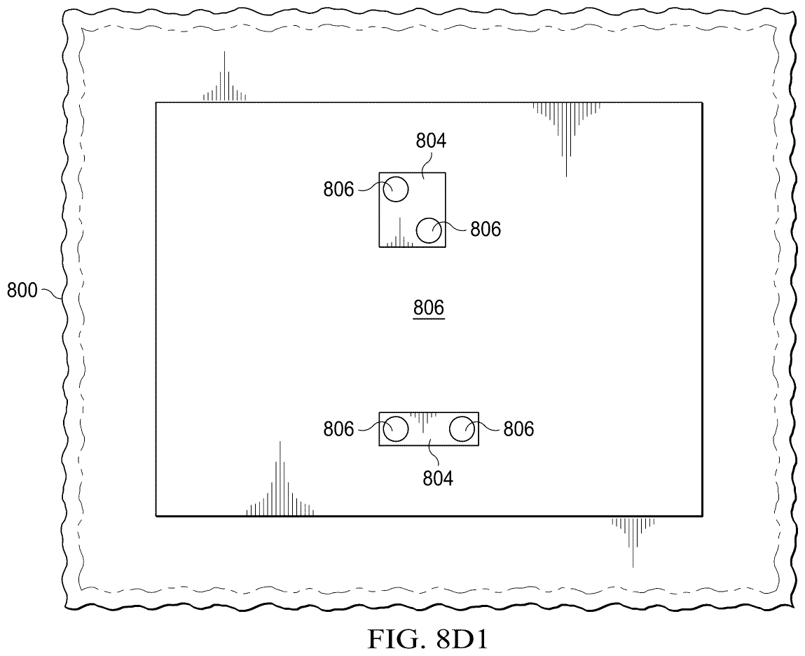

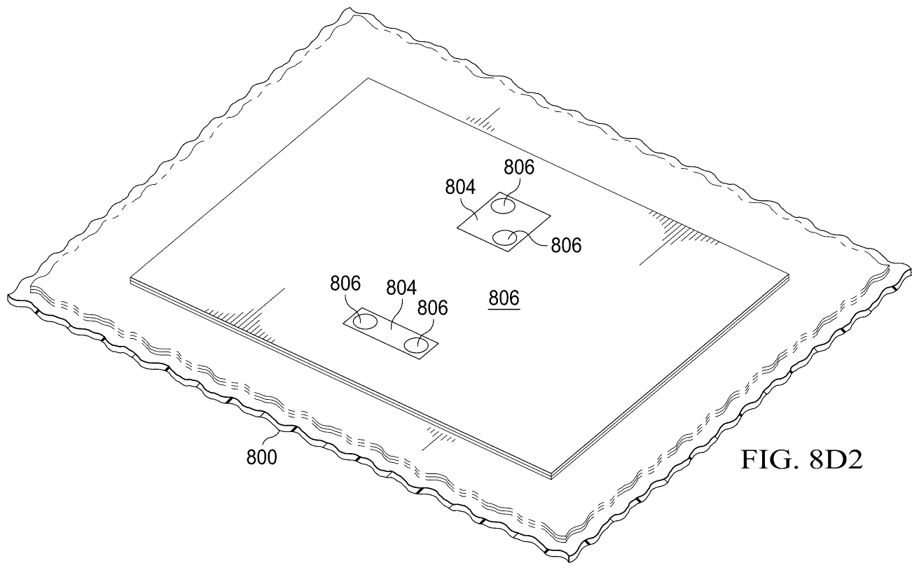

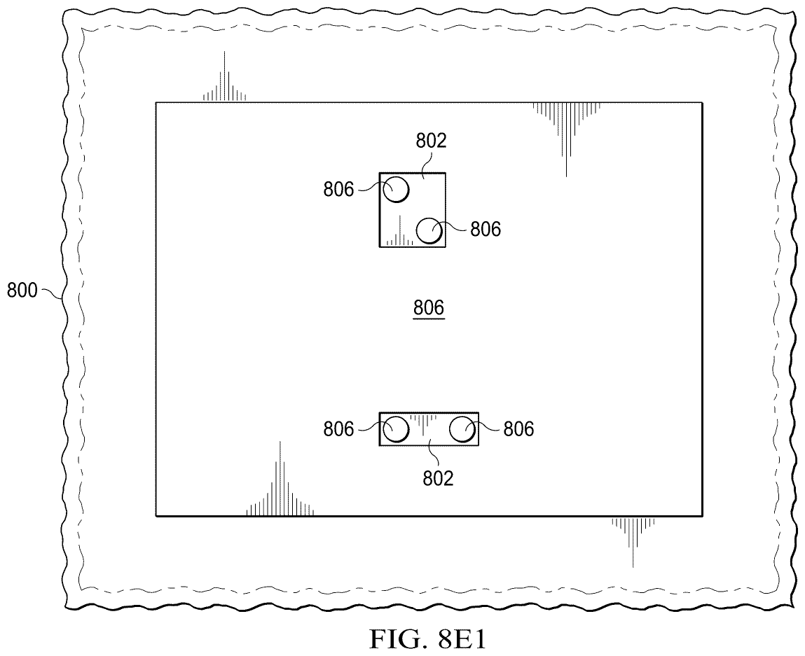

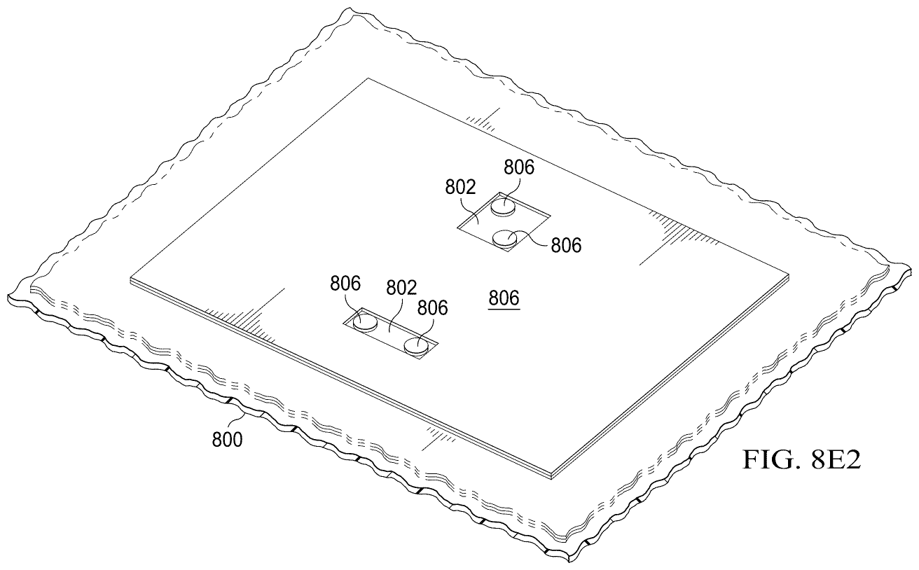

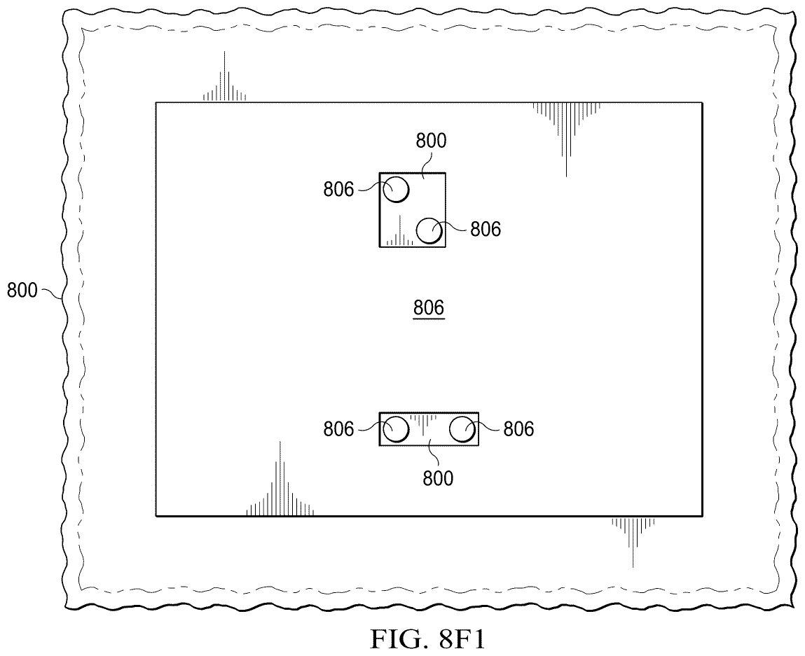

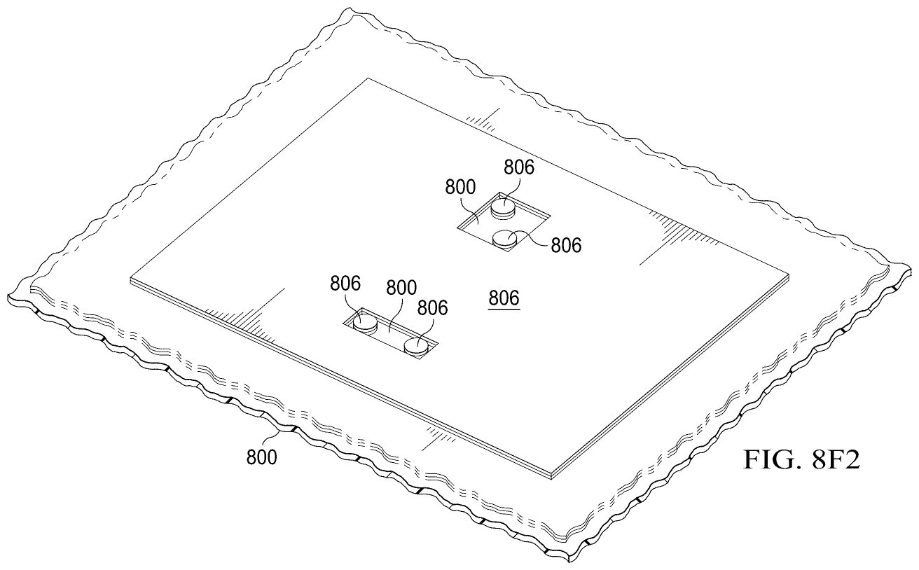

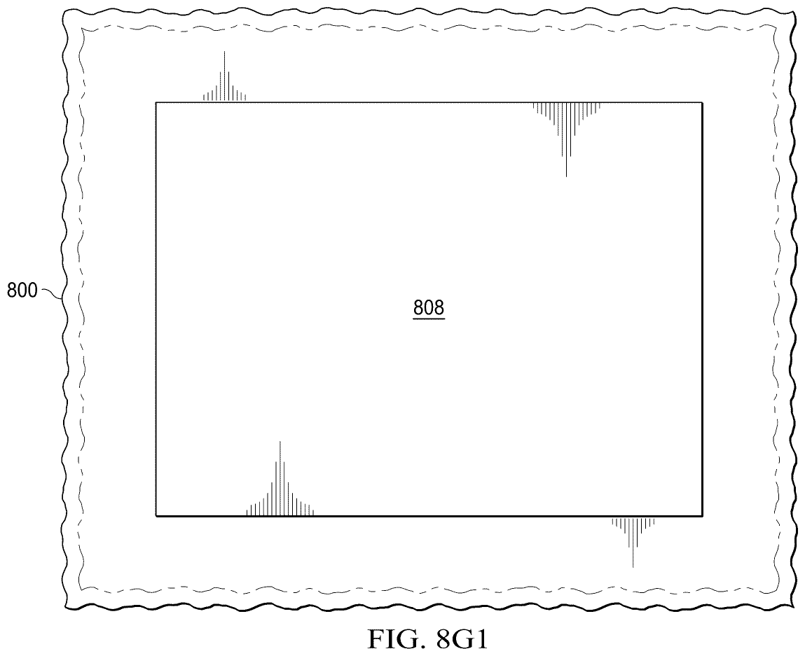

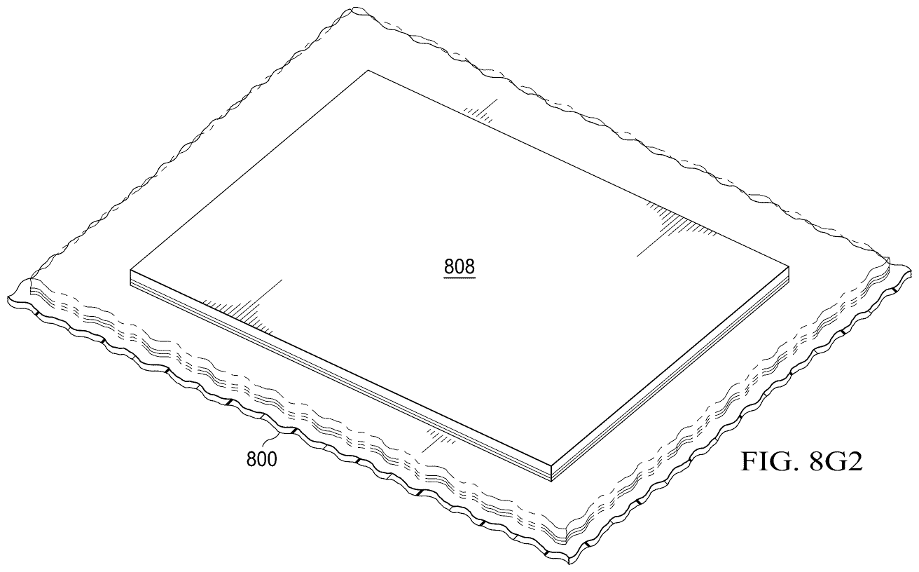

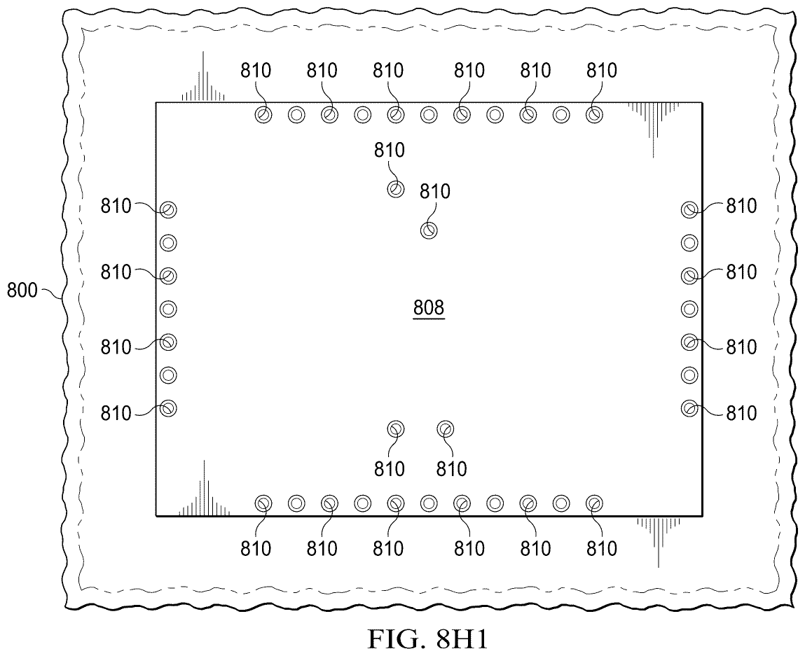

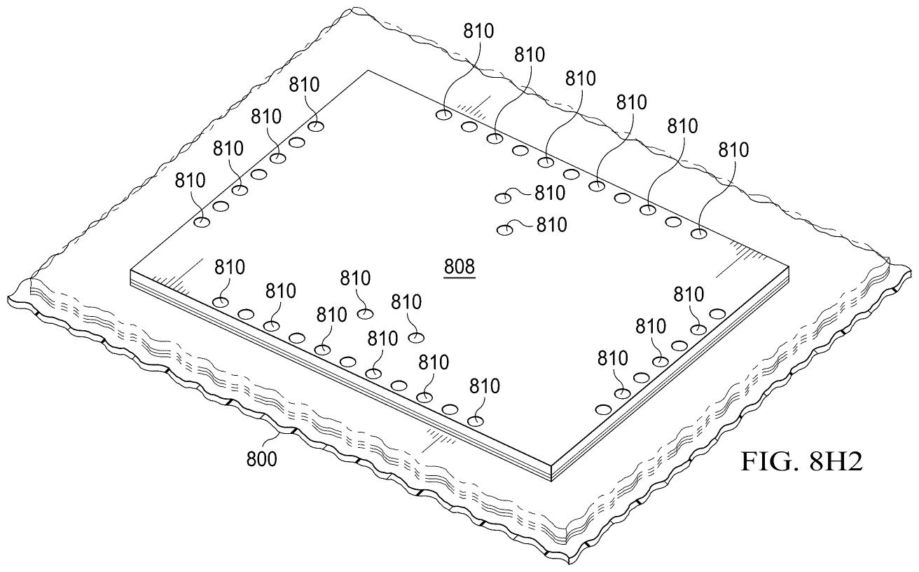

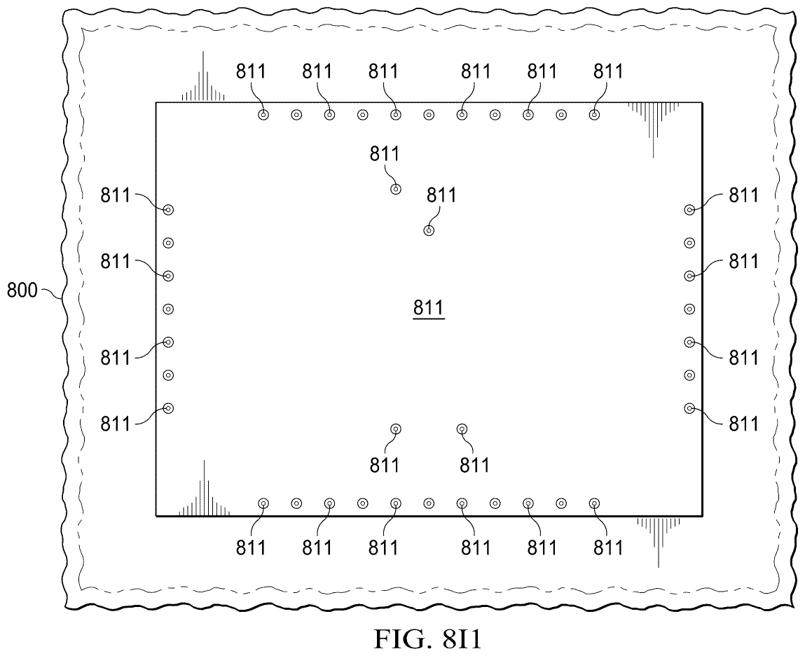

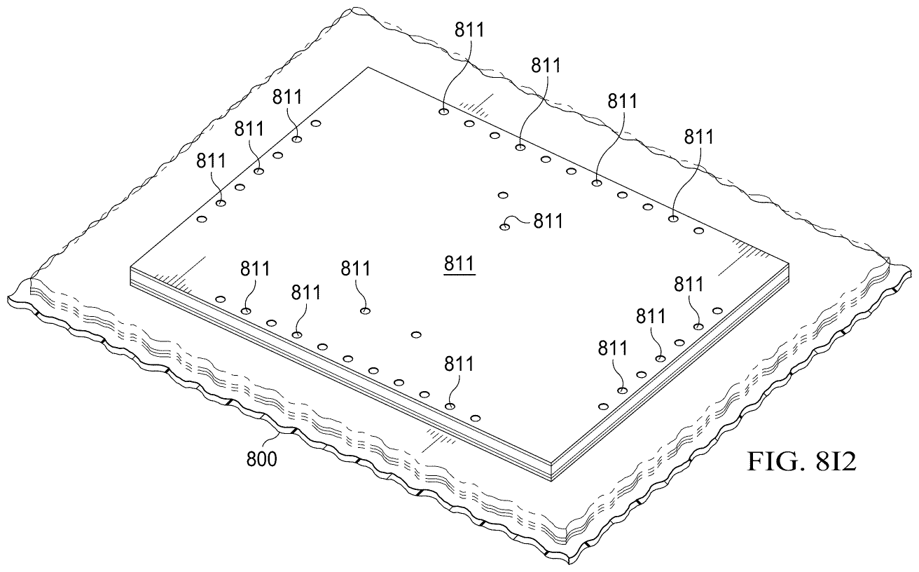

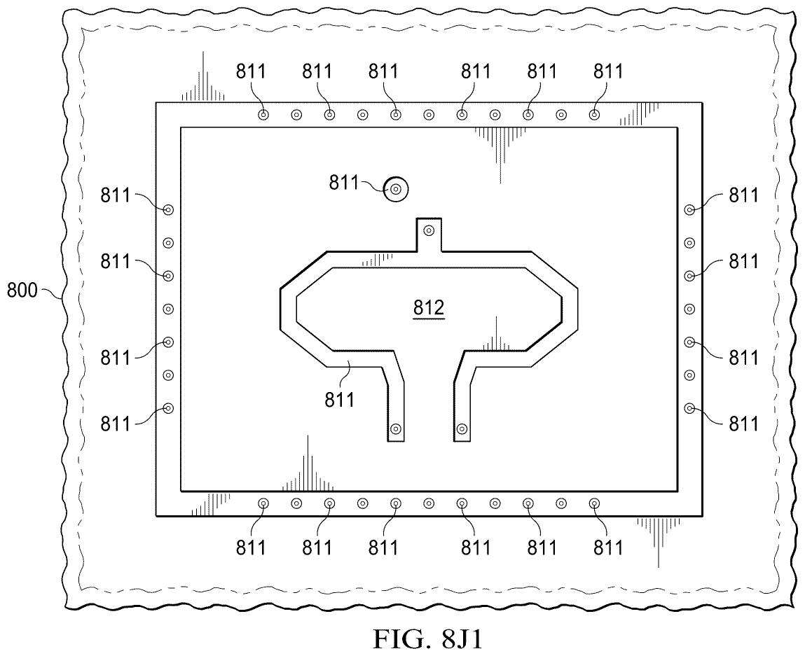

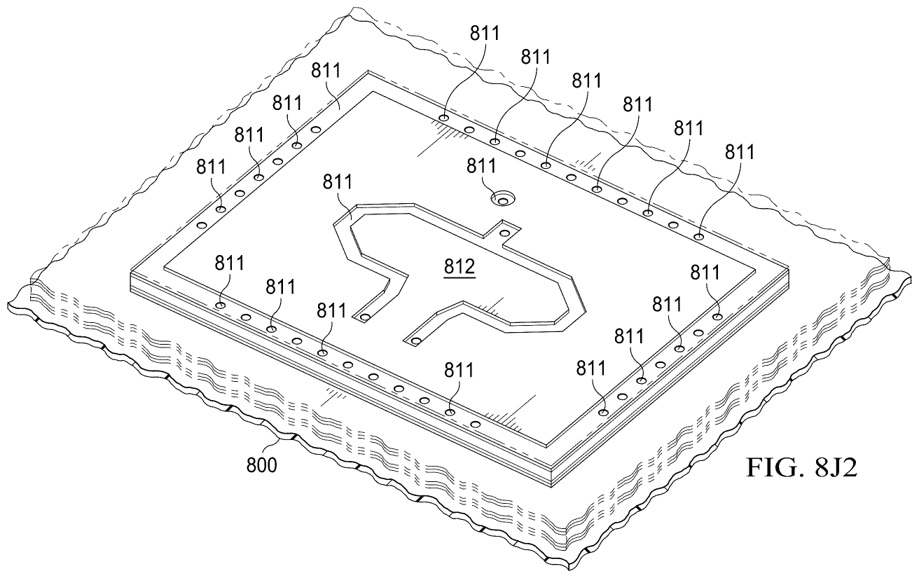

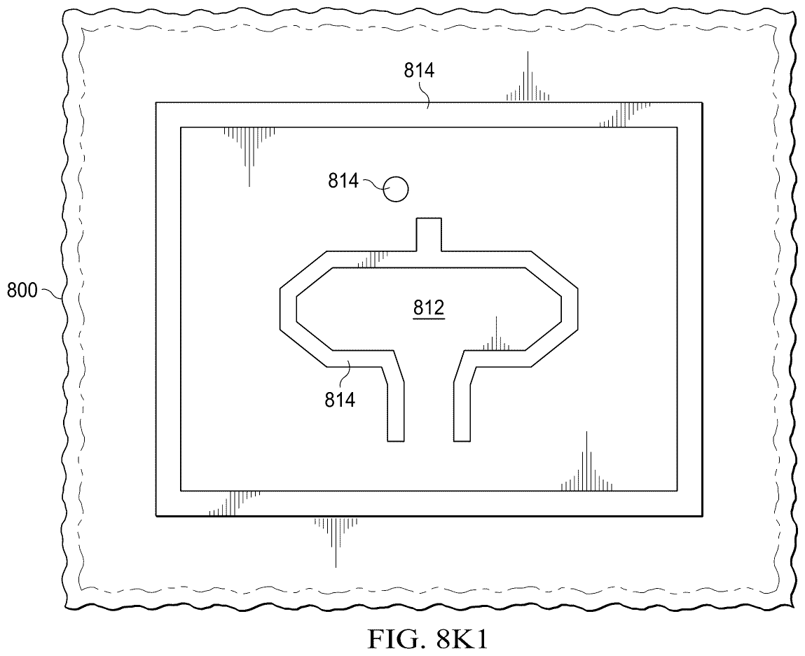

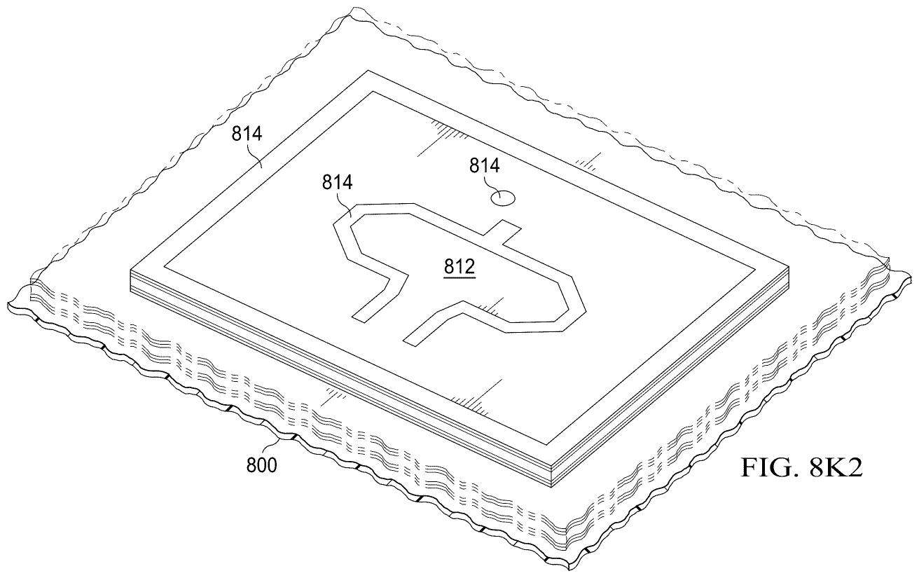

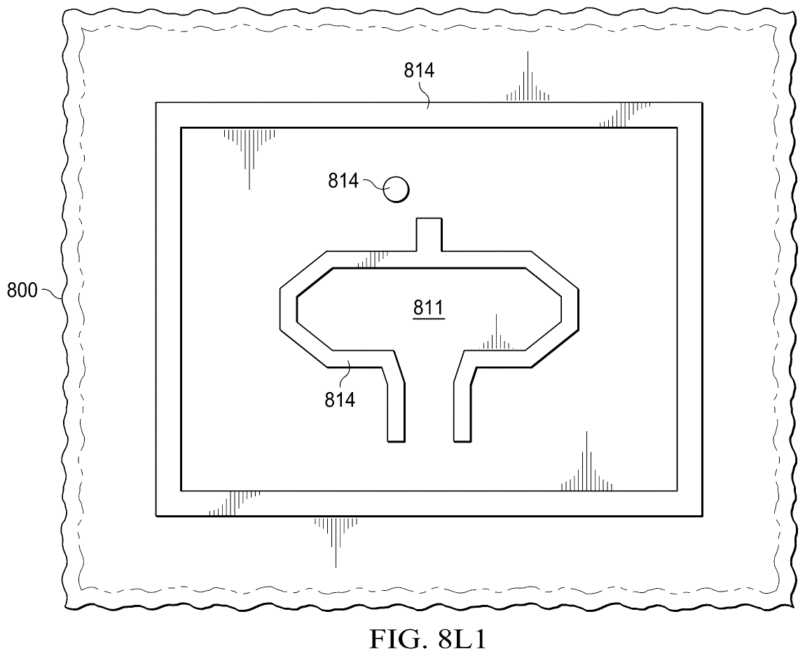

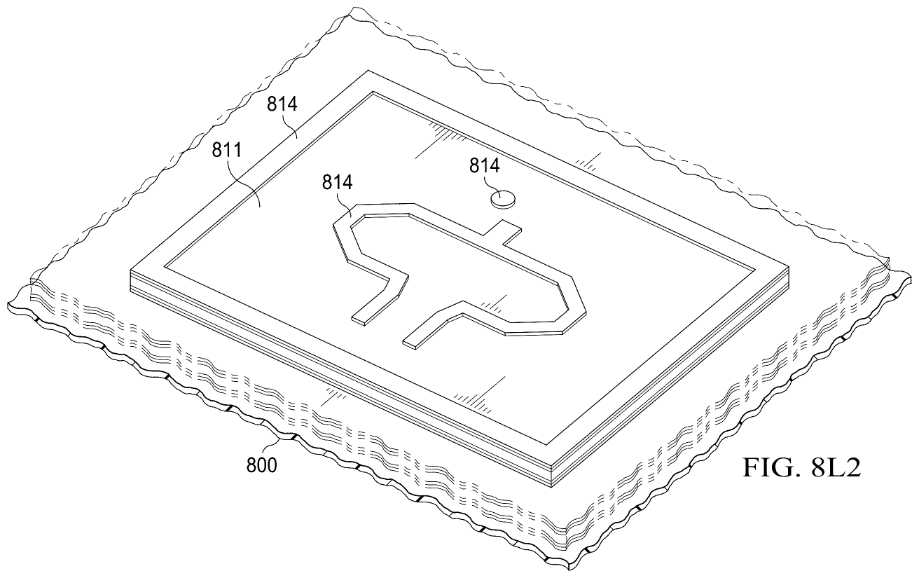

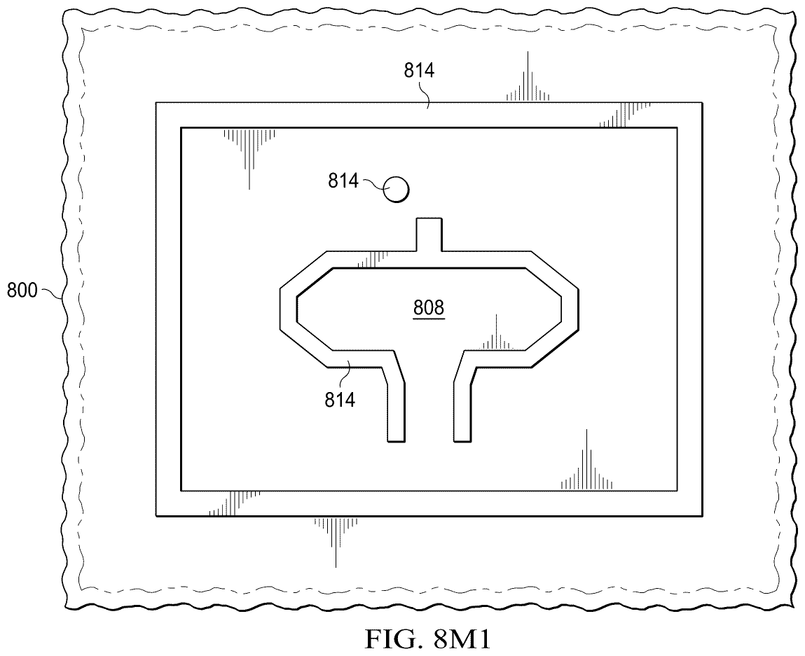

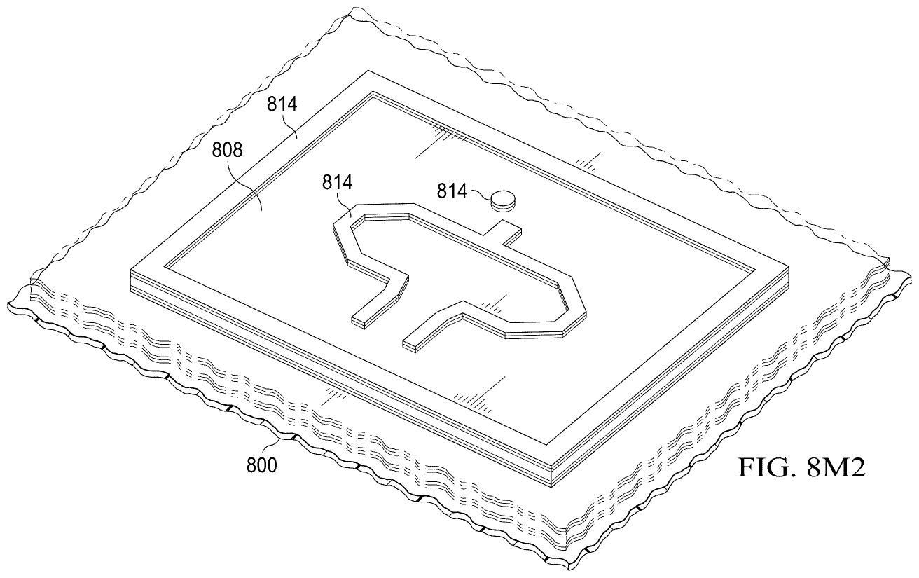

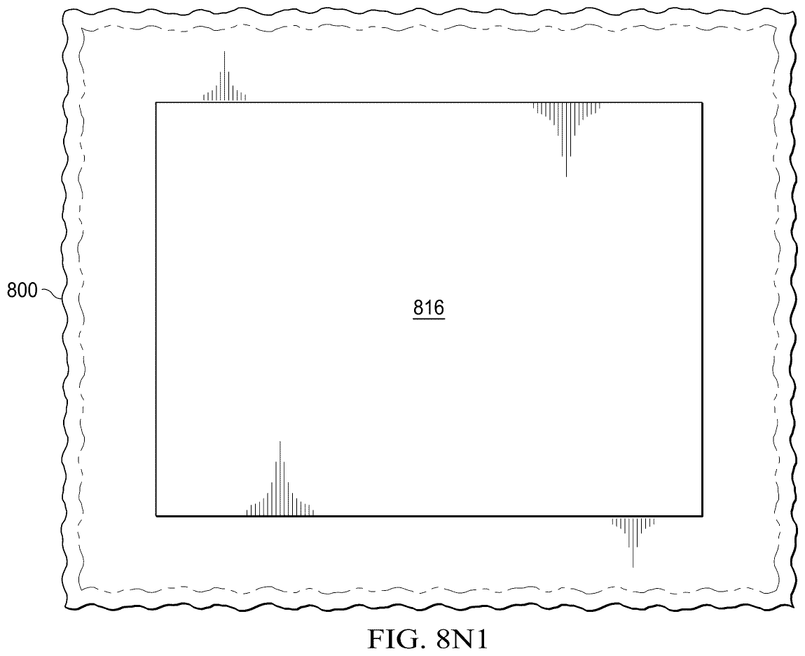

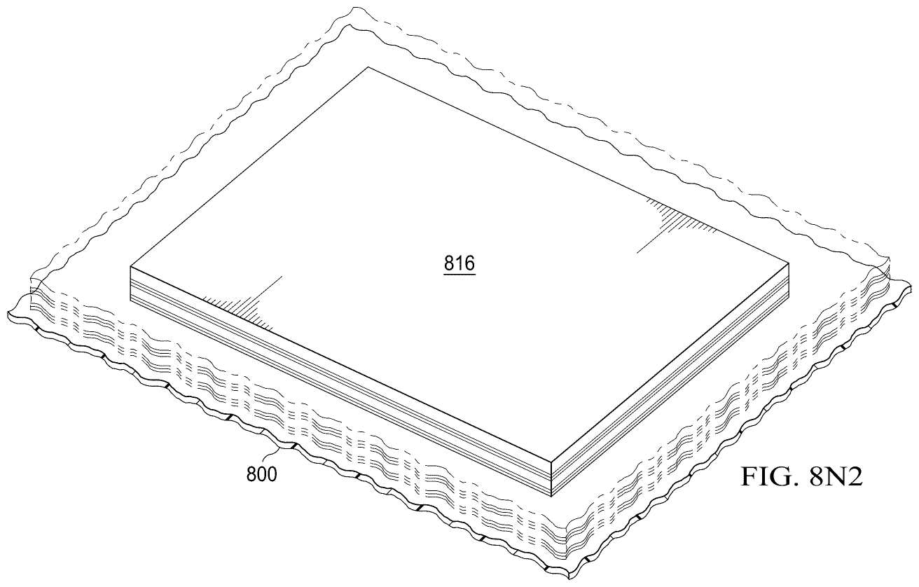

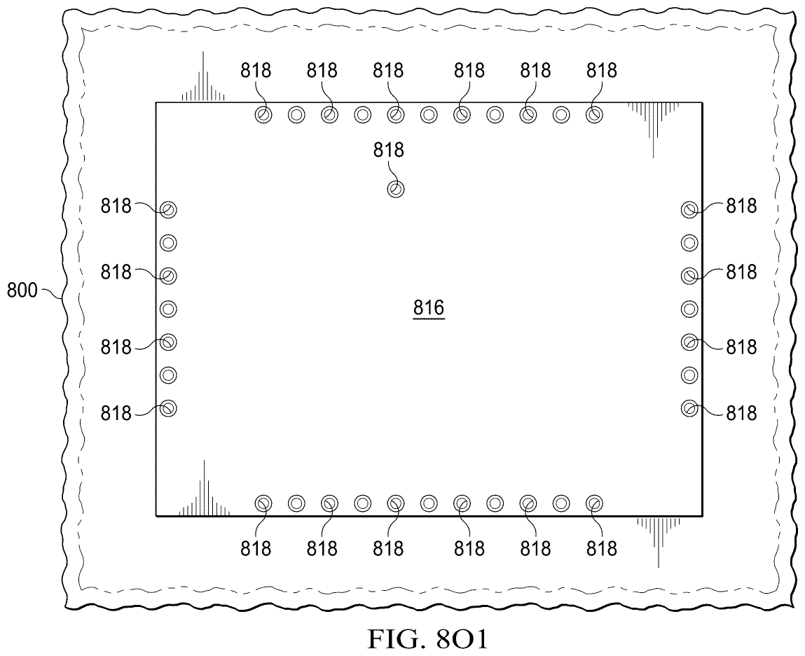

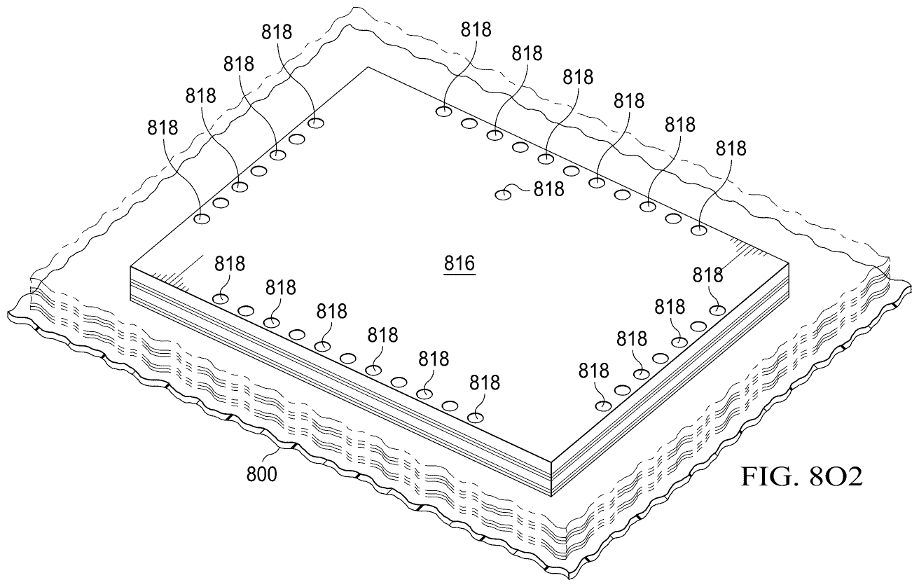

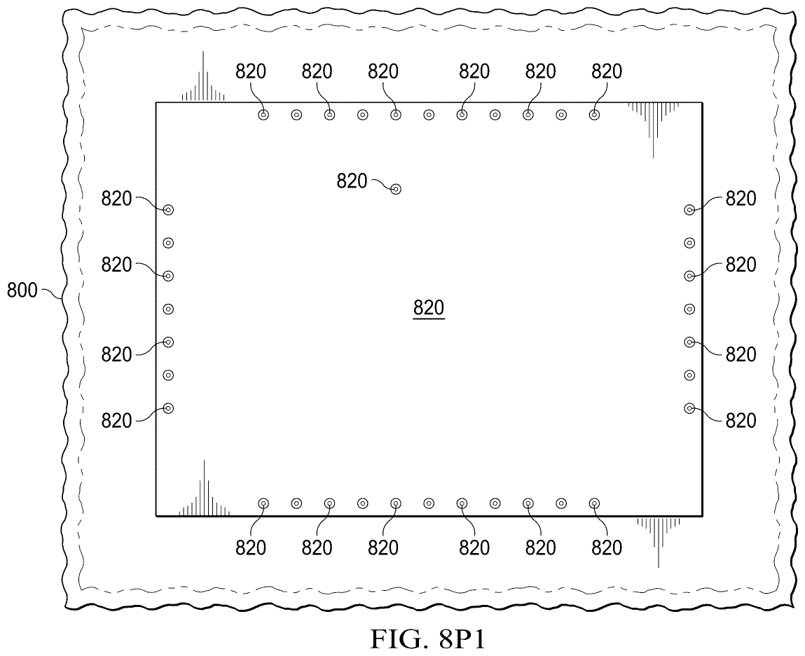

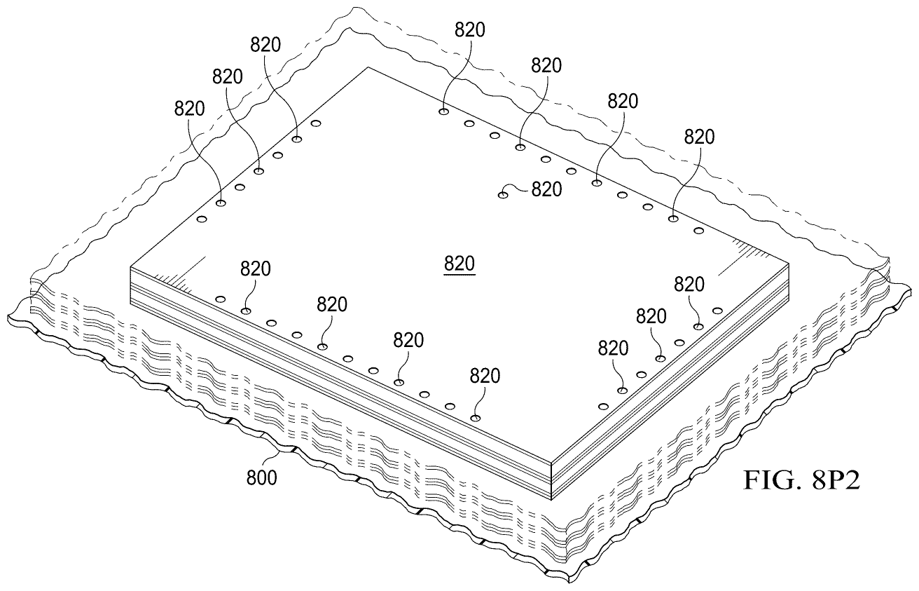

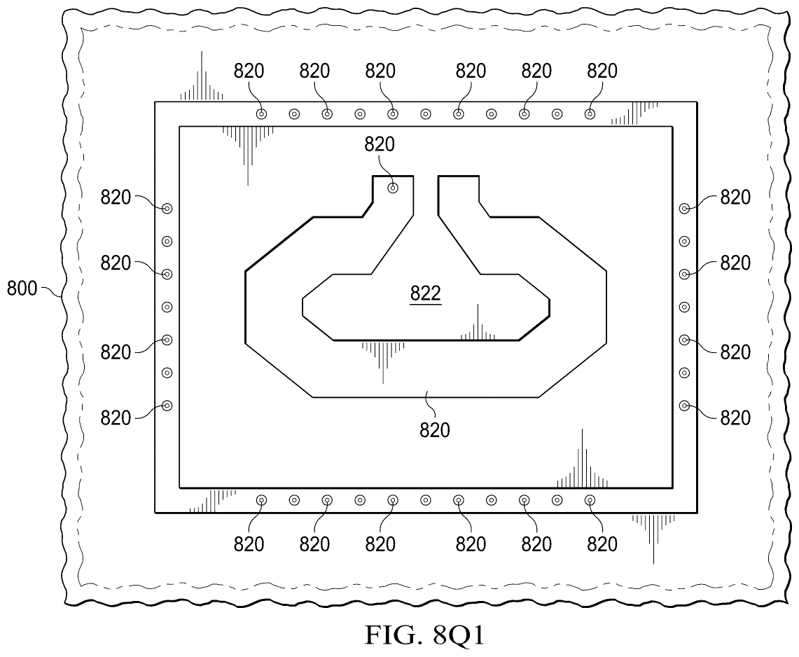

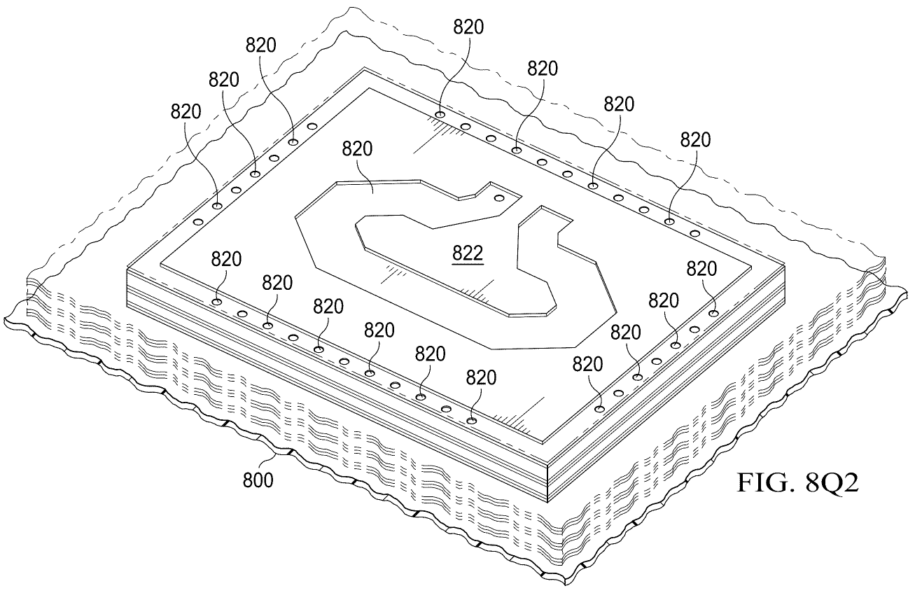

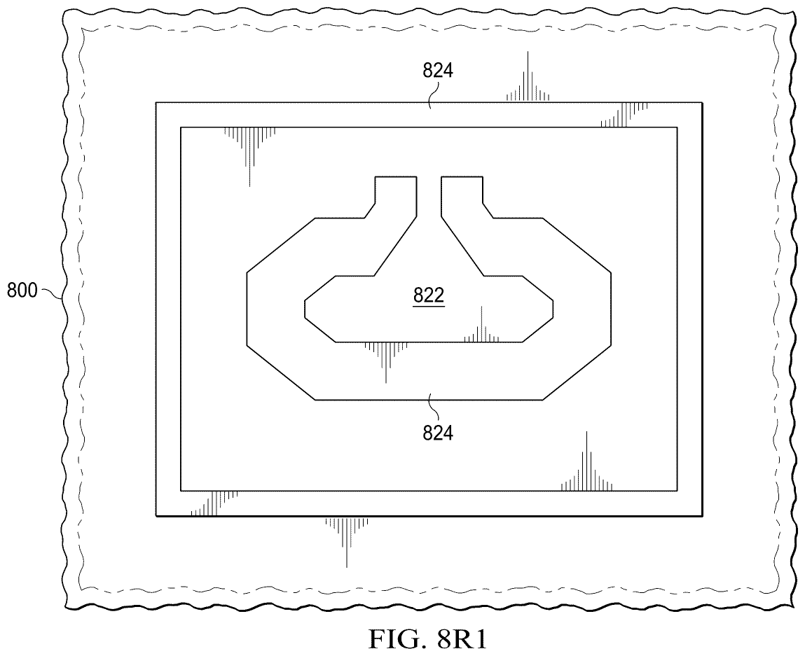

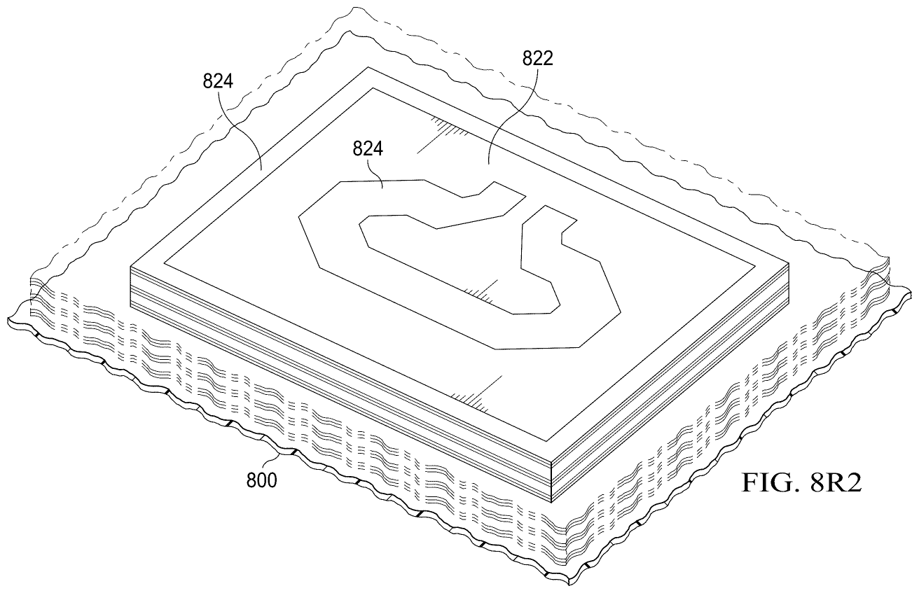

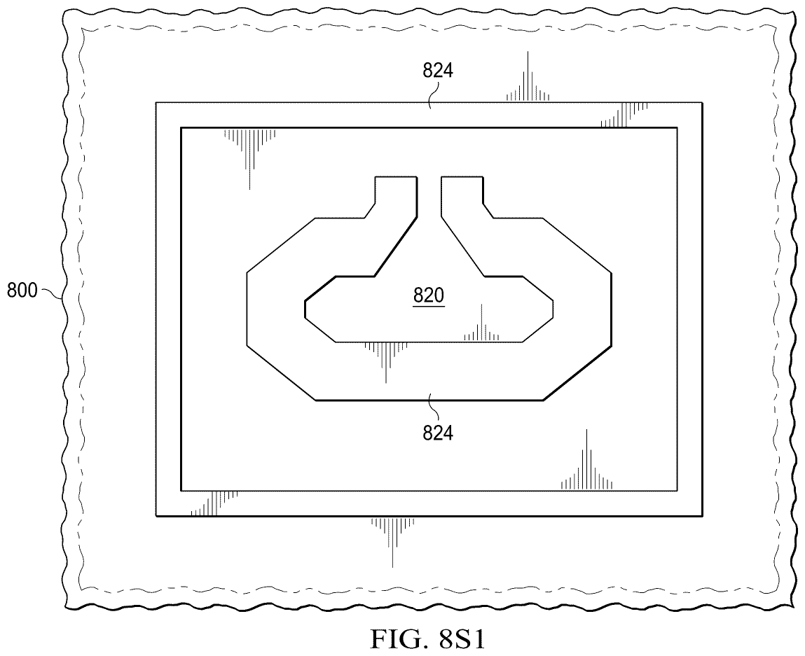

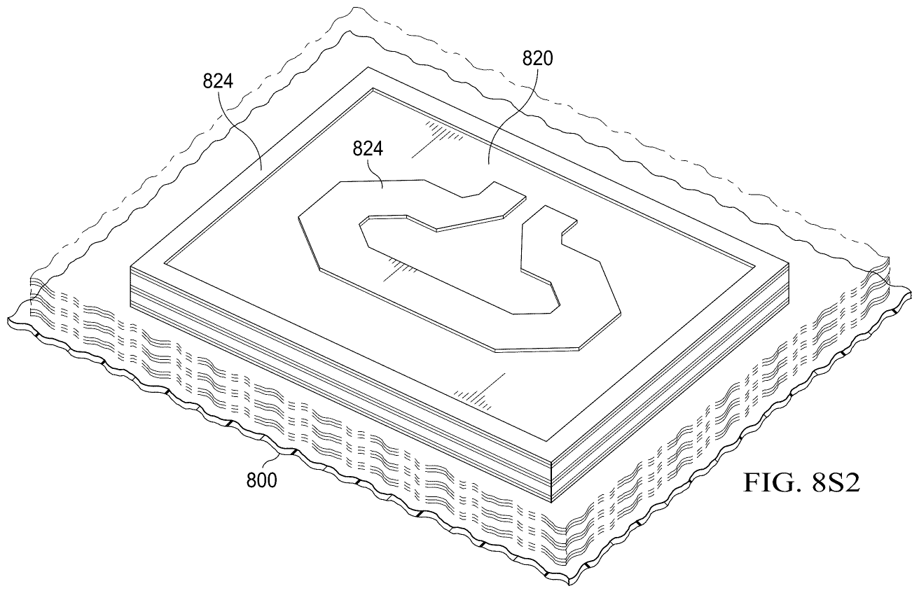

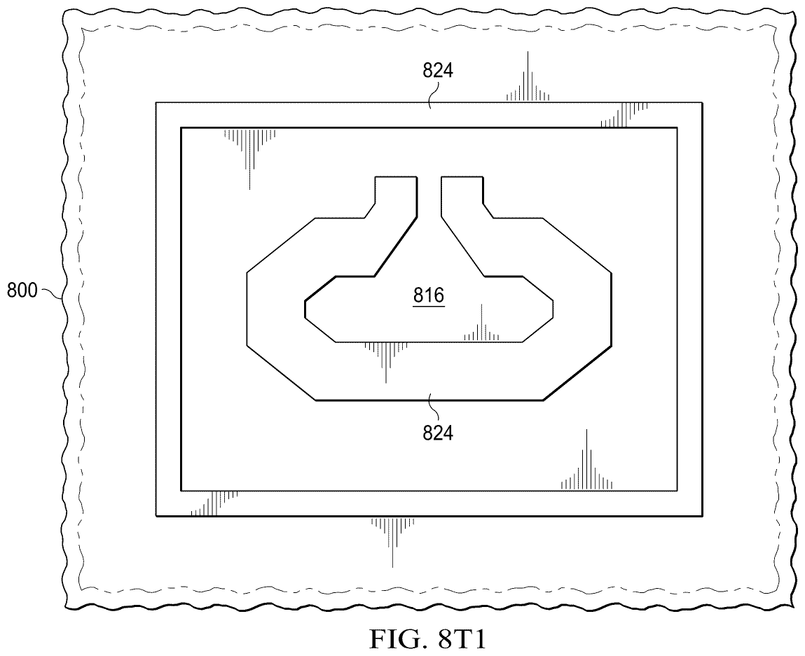

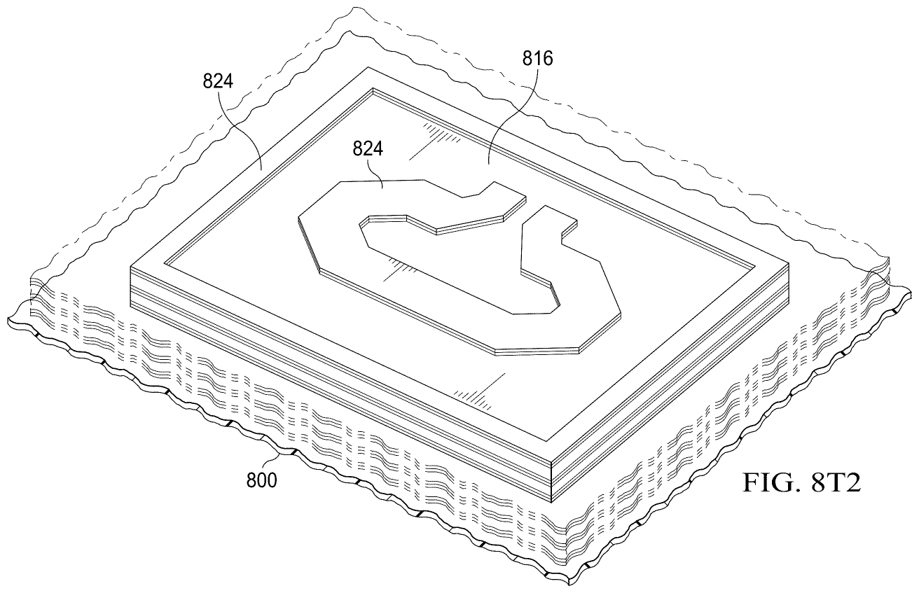

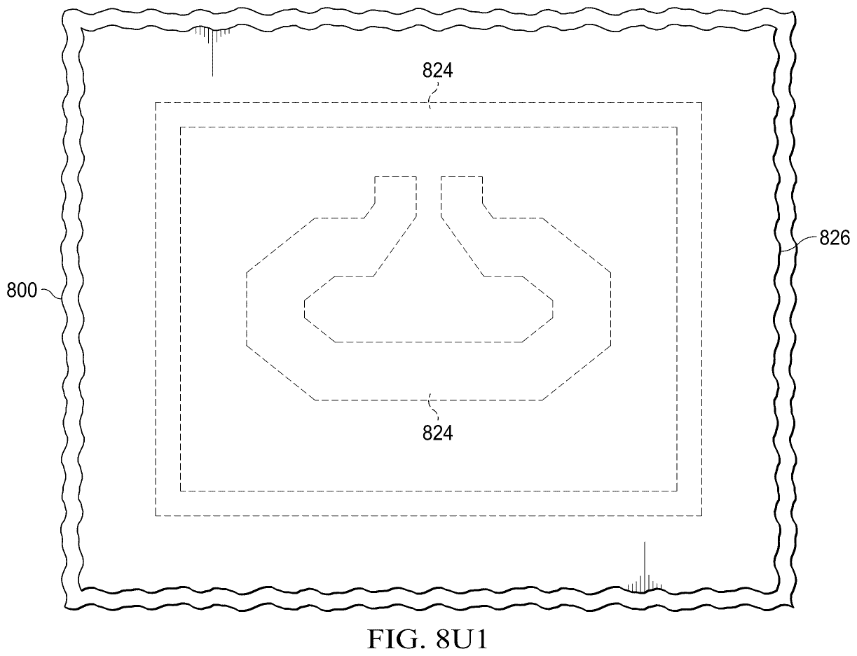

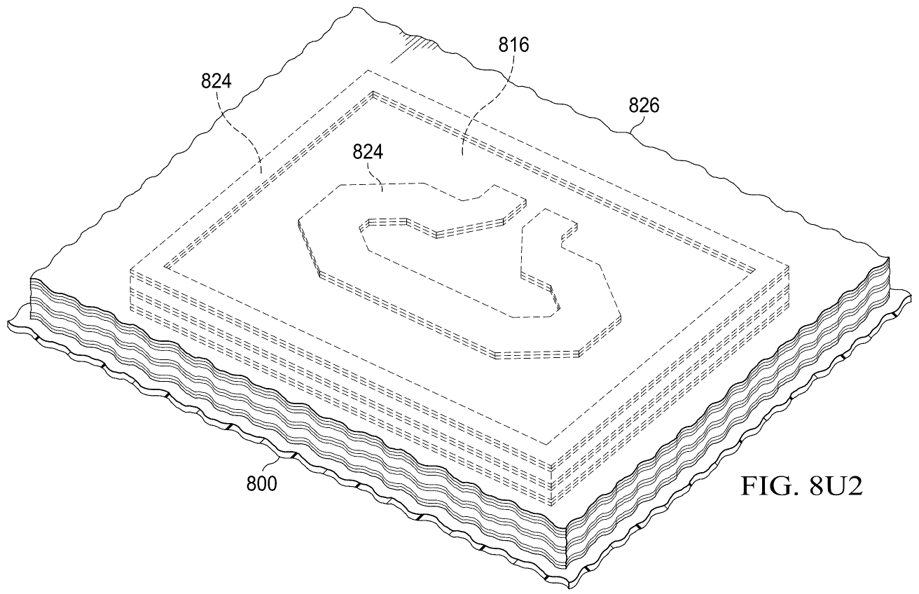

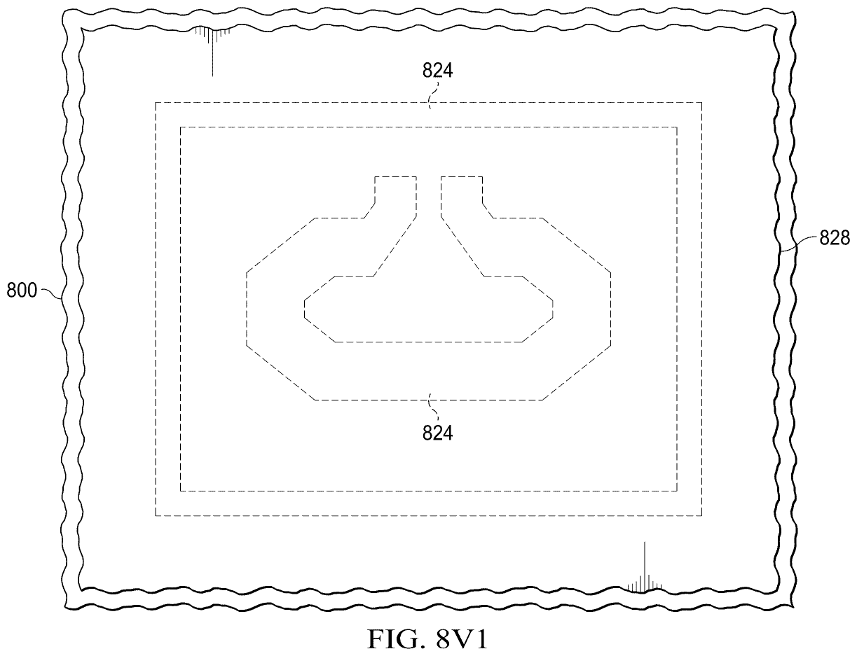

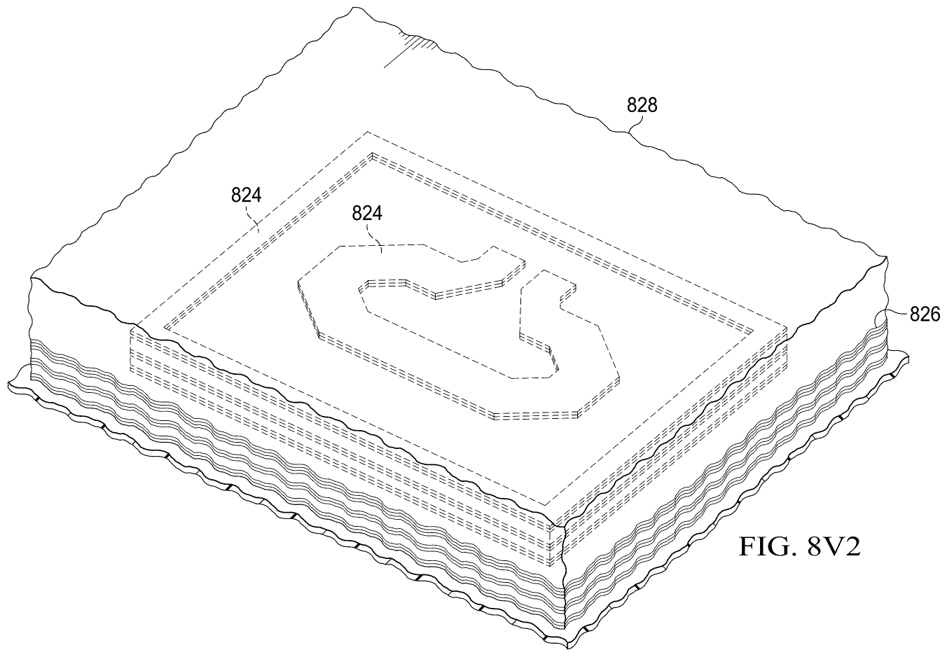

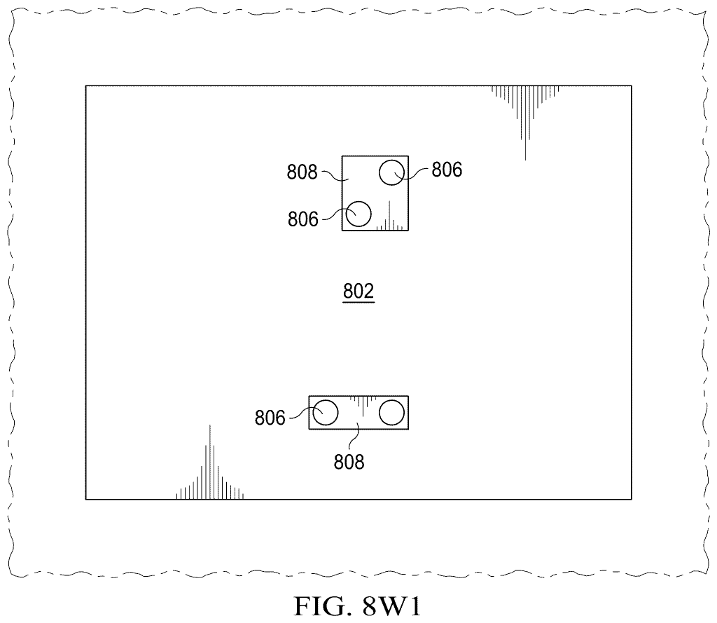

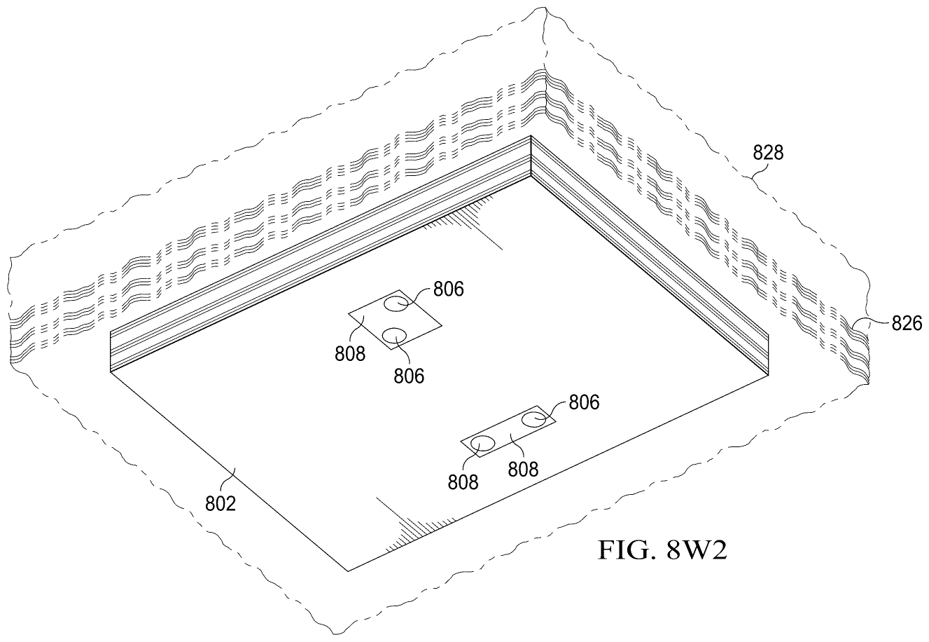

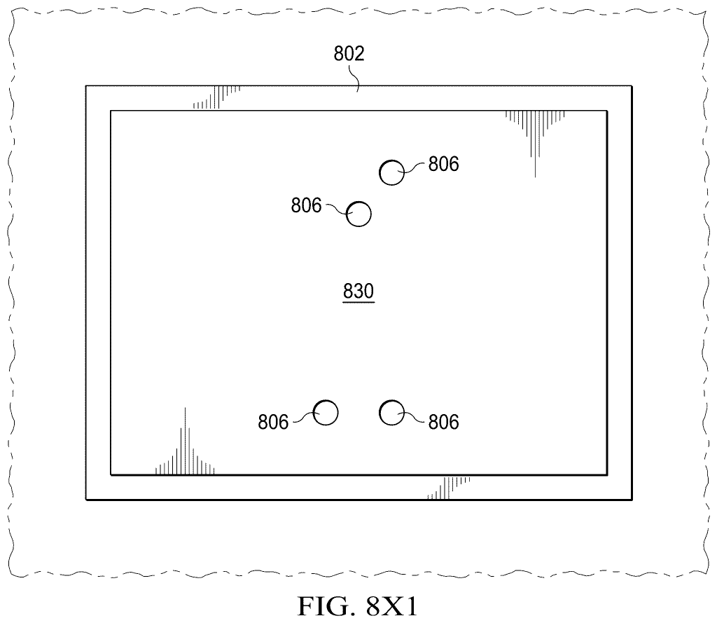

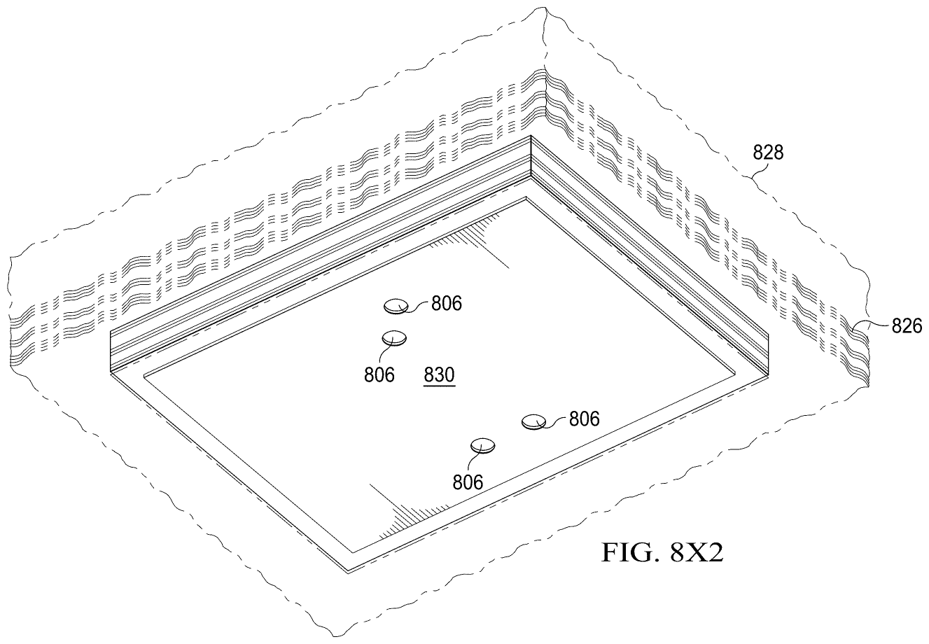

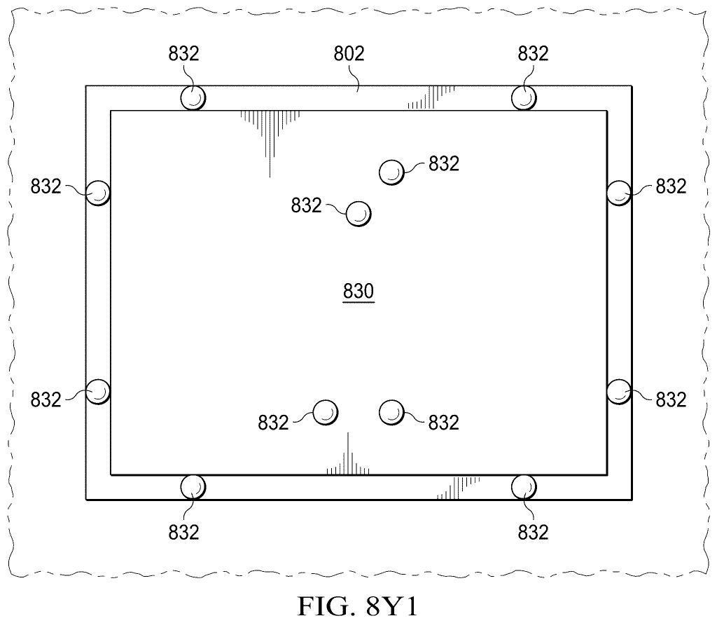

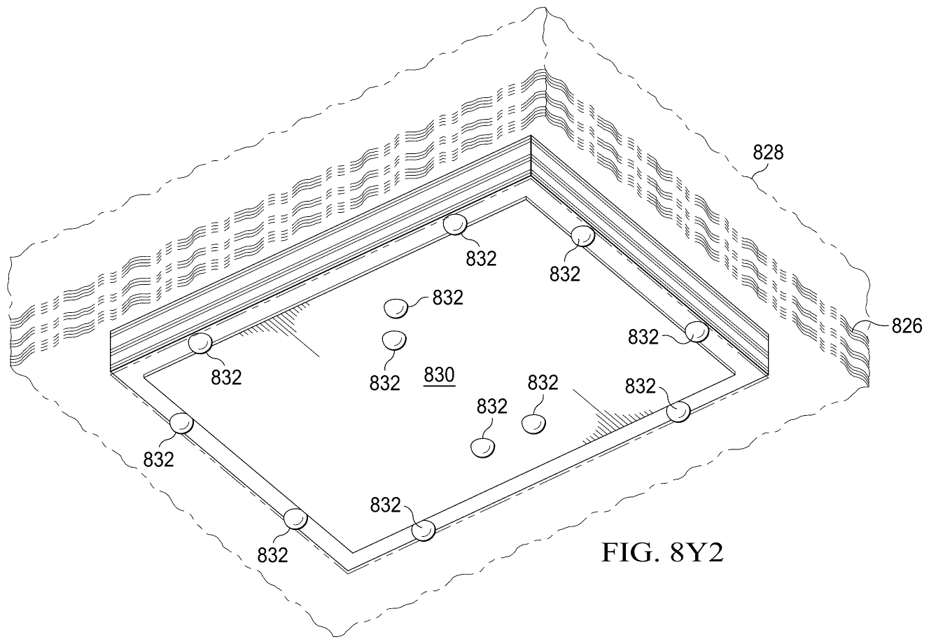

FIGS. 7A and 7B depict a flow diagram of a method 700 for manufacturing a semiconductor package including a package substrate having a Marchand balun, such as the semiconductor package 400 of FIGS. 4A-4D, in accordance with various examples. FIG. 8A1, 8A2, 8B1, 8B2, 8C1, 8C2, 8D1, 8D2, 8E1, 8E2, 8F1, 8F2, 8G1, 8G2, 8H1, 8H2, 8I1, 8I2, 8J1, 8J2, 8K1, 8K2, 8L1, 8L2, 8M1, 8M2, 8N1, 8N2, 8O1, 8O2, 8P1, 8P2, 8Q1, 8Q2, 8R1, 8R2, 8S1, 8S2, 8T1, 8T2, 8U1, 8U2, 8V1, 8V2, 8W1, 8W2, 8X1, 8X2, 8Y1, and 8Y2 are a process flow for manufacturing a semiconductor package including a package substrate having a Marchand balun, such as the semiconductor package 400 of FIGS. 4A-4D, in accordance with various examples. Accordingly, FIGS. 7 and 8A1-8Y2 are now described in parallel.

The method 700 includes depositing first and second metal seed layers on first and second opposing sides of a carrier, respectively (702). Although the method 700 assumes manufacture of semiconductor packages on both sides of a carrier, for simplicity of description, FIG. 8A1-8Y2 depict manufacture of only one semiconductor package. FIG. 8A1-8Y2 provide top-down and perspective views unless denoted otherwise. FIG. 8A1 and 8A2 depict top-down and perspective views of a carrier 800, and FIG. 8B1 and 8B2 depict top-down and perspective views of the carrier 800 having a seed layer 802 (e.g., a copper seed layer) deposited on the carrier 800.

The method 700 includes patterning first and second photoresist layers on the first and second metal seed layers, respectively (704). FIG. 8C1 and 8C2 depict top-down and perspective views of the structure of FIG. 8B1 and 8B2, except that a photoresist layer 804 is applied to the seed layer 802. The photoresist layer 804 has been patterned according to any suitable photolithography technique, for example, using an appropriately patterned mask and light to expose specific areas of the photoresist layer 804, appropriate chemical solution to develop the exposed areas of the photoresist layer 804, etc. As shown, the photoresist layer 804 isolates four areas of the seed layer 802 from the remainder of the seed layer 802. These four isolated areas of the seed layer 802 will later form contact points on the bottom surface of the semiconductor package to which solder bumps may be coupled for attachment to a PCB.

The method 700 includes plating first and second metal layers using the first and second metal seed layers and the first and second photoresist layers, respectively, with the first and second metal layers forming ground planes (706). FIG. 8D1 and 8D2 are top-down and perspective views of the structure of FIG. 8C1 and 8C2, except that the portions of the seed layer 802 not covered by the photoresist layer 804 are plated and thus thickened relative to the seed layer 802. The thickness of the resulting plated metal layer 806 is the same as that of the photoresist layer 804. The portions of the plated metal layer 806 surrounded by the photoresist layer 804 form parts of the vias described above (e.g., the vias 214, 216, 218, 314 in FIGS. 4A-4D). The remainder of the plated metal layer 806 forms the ground plane described above (e.g., the metal layer 406).

The method 700 includes removing the first and second photoresist layers and portions of the first and second metal seed layers (708). FIG. 8E1 and 8E2 are top-down and perspective views of the structure of FIG. 8D1 and 8D2, except that the photoresist layer 804 is removed, and FIG. 8F1 and 8F2 are top-down and perspective views of the structure of FIG. 8E1 and 8E2, except that the metal seed layer 802 underneath the photoresist layer 804 is removed (e.g., by etching).

The method 700 includes applying first and second dielectric layers on the first and second metal layers, respectively (710). FIG. 8G1 and 8G2 are top-down and perspective views of the structure of FIG. 8F1 and 8F2, except that a dielectric layer 808 has been applied across the top of the structure. As described, the dielectric layer 808 may be pre-preg, for example.

The method 700 includes drilling (e.g., laser drilling) first and second via holes in the first and second dielectric layers, respectively (712). FIG. 8H1 and 8H2 are top-down and perspective views of the structure of FIG. 8G1 and 8G2, except that holes 810 have been drilled in the dielectric layer 808 to facilitate the passage of vias through the dielectric layer 808. Some of the holes 810 may be drilled along a perimeter of the dielectric layer 808, and ground wall vias (e.g., the vias 414, 530, and the vias in the ground wall 634, such as in FIGS. 4A-4D, 5A-5E, and 6A-6C) will subsequently extend through these holes 810. Some of the holes 810 are vertically aligned with the metals circumscribed by the photoresist layer 804 in FIG. 8D1 and 8D2, so that the vias that will later extend through the holes 810 will make physical contact with the metals circumscribed by the photoresist layer 804 in FIG. 8D1 and 8D2.

The method 700 includes depositing third and fourth metal seed layers on the first and second dielectric layers, respectively, including inside the first and second via holes, respectively (714). FIG. 8I1 and 8I2 are top-down and perspective views of the structure of FIG. 8H1 and 8H2, except that a metal seed layer 811 (e.g., copper) has been applied (e.g., sputtered) across the entire surface of the structure in FIG. 8H1 and 8H2, including inside the holes 810.

The method 700 includes patterning third and fourth photoresist layers on the third and fourth metal seed layers, respectively (716). FIG. 8J1 and 8J2 are top-down and perspective views of the structure of FIG. 8I1 and 8I2, respectively, except that a photoresist layer 812 is patterned on the seed layer 811 of FIG. 8I1 and 8I2. The photoresist layer 812 is patterned to expose a portion of the seed layer 811 in the shape of the metal layer 200 (FIGS. 2A-2D), for example. Further, the photoresist layer 812 is patterned to expose a portion of the seed layer 811 in the shape of a via (e.g., via 314) that will facilitate connection to a future metal layer, e.g., the metal layer 300 (FIGS. 3A-3D), as described below.

The method 700 includes plating first and second vias in the first and second via holes using the third and fourth metal seed layers, respectively (718). The method 700 also includes plating third and fourth metal layers using the third and fourth metal seed layers and the third and fourth photoresist layers, respectively (720). The third metal layer includes a first end and a second end opposing the first end, and the fourth metal layer includes a third end and a fourth end opposing the third end (720). A body of the third metal layer between the first and second ends has an open curve shape and a first width, and a body of the fourth metal layer between the third and fourth ends has the open curve shape and a second width (720). The third and fourth metal layers physically contact the first and second vias, respectively (720). FIG. 8K1 and 8K2 are top-down and perspective views of the structure of FIG. 8J1 and 8J2, except that the portions of the metal seed layer 811 not covered by the photoresist layer 812 are plated (e.g., electroplated) to form a plated metal layer 814, thereby increasing the thickness of the seed layer 811 in those areas not covered by the photoresist layer 812. The photoresist layer 812 circumscribes the metal layer (e.g., the metal layer 200) and the via (e.g., the via 314), with the metal layer having the physical features described in step 720.

The method 700 includes removing the third and fourth photoresist layers and portions of the third and fourth metal seed layers (722). FIG. 8L1 and 8L2 are top-down and perspective views of the structure of FIG. 8K1 and 8K2, except that the photoresist layer 812 has been removed. FIG. 8M1 and 8M2 are top-down and perspective views of the structure of FIG. 8L1 and 8L2, except that the portions of the seed layer that were covered by the photoresist layer 812 are removed (e.g., etched away).

The method 700 includes applying third and fourth dielectric layers to the third and fourth metal layers, respectively (724). FIG. 8N1 and 8N2 are top-down and perspective views of the structure of FIG. 8M1 and 8M2, except that a dielectric layer 816 (e.g., pre-preg) is applied to the entire surface of the structure of FIG. 8M1 and 8M2.

The method 700 includes drilling (e.g., laser drilling) third and fourth via holes in the third and fourth dielectric layers, respectively (726). FIG. 8O1 and 8O2 are top-down and perspective views of the structure of FIG. 8N1 and 8N2, except that the dielectric layer 816 includes multiple holes 818. Some of the holes 818 may be drilled along a perimeter of the dielectric layer 816, and ground wall vias (e.g., the vias 414, 530, and the vias in the ground wall 634, such as in FIGS. 4A-4D, 5A-5E, and 6A-6C) will subsequently extend through these holes 818. One of the holes 818 is vertically aligned with the metal circumscribed by the photoresist layer 812 in FIG. 8K1 and 8K2, so that the via (e.g., via 314, FIGS. 4A-4D) that will later extend through that hole 818 will make physical contact with the metal circumscribed by the photoresist layer 812 in FIG. 8K1 and 8K2.

The method 700 includes depositing fifth and sixth metal seed layers on the third and fourth dielectric layers, respectively, including inside the third and fourth via holes, respectively (728). FIG. 8P1 and 8P2 are top-down and perspective views of the structure of FIG. 8O1 and 8O2, except that a seed layer 820 is applied (e.g., sputtered) onto the entire surface of the structure of FIG. 8O1 and 8O2, including inside the holes 818, as shown.

The method 700 includes patterning fifth and sixth photoresist layers on the fifth and sixth metal seed layers, respectively (730). FIG. 8Q1 and 8Q2 are top-down and perspective views of the structure of FIG. 8P1 and 8P2, except that a photoresist layer 822 is applied to the seed layer 820. The photoresist layer 822 defines a metal layer shape, such as that of the metal layer 300 (FIGS. 3A-3D). The location of the metal layer shape within the photoresist layer 822 is such that an end of the metal layer shape is vertically aligned with the sole non-ground wall via shown in FIG. 8O1-8P2.

The method 700 includes plating third and fourth vias in the third and fourth via holes using the fifth and sixth metal seed layers, respectively (732). The method 700 also includes plating fifth and sixth metal layers using the fifth and sixth metal seed layers and the fifth and sixth photoresist layers, respectively (734). The fifth metal layer includes a fifth end and a sixth end opposing the fifth end, and a body of the fifth metal layer between the fifth and sixth ends has the open curve shape and a third width greater than the first width (734). The third and fifth metal layers form a first Marchand balun, and the sixth metal layer includes a seventh end and an eighth end opposing the seventh end (734). A body of the sixth metal layer between the seventh and eighth ends has the open curve shape and a fourth width greater than the second width (734). The fourth and sixth metal layers form a second Marchand balun, with the fifth and sixth metal layers physically contacting the third and fourth vias, respectively (734). FIG. 8R1 and 8R2 are top-down and perspective views of the structure of FIG. 8Q1 and 8Q2, except that the areas of the seed layer 820 that are not covered by the photoresist layer 822 are plated (e.g., electroplated), and thus thickened, to produce the plated metal layer 824. The portion of the plated metal layer 824 defined by the photoresist layer 822 is similar to the metal layer 300 (FIGS. 3A-3D), for example.

The method 700 includes removing the fifth and sixth photoresist layers and portions of the fifth and sixth metal seed layers (736). FIG. 8S1 and 8S2 are top-down and perspective views of the structure of FIG. 8R1 and 8R2, except that the photoresist layer 822 has been removed (e.g., stripped), and FIG. 8T1 and 8T2 are top-down and perspective views of the structure of FIG. 8S1 and 8S2, except that portions of the seed layer 820 that were covered by the photoresist layer 822 are removed (e.g., etched away).

The method 700 includes removing the carrier (738) and applying a first solder mask to the first metal layer and a second solder mask to the fifth metal layer (740). The method 700 also includes applying a mold compound to the second solder mask (742). FIG. 8U1 and 8U2 are top-down and perspective views of the structure of FIG. 8T1 and 8T2, except that a solder mask 826 is applied to the top surface of the structure of FIG. 8T1 and 8T2. FIG. 8V1 and 8V2 are top-down and perspective views of the structure of FIG. 8U1 and 8U2, except that a mold compound 828 is applied to the top surface of the solder mask 826.

The method 700 includes applying a solder mask to a bottom surface of the structure (744) and coupling solder bumps to the bottom surface of the structure (746). FIG. 8W1 and 8W2 are bottom-up and perspective views of the structure of FIG. 8V1 and 8V2. The exposed areas of the metal layer 806 defined by the dielectric layer 808 are coupled to the vias of the semiconductor package (e.g., the vias 214, 216, 218, 314, FIGS. 4A-4D). The remainder of the metal layer 806 is the ground plane (e.g., metal layer 406, FIGS. 4A-4D), and couples to the ground wall (e.g., ground wall 418, FIGS. 4A-4D) and ground wall vias (e.g., vias 414, FIGS. 4A-4D). The exposed areas of the metal layer 806 defined by the dielectric layer 808 may be considered to be metal contacts that are approximately flush (i.e., flush or within 50 microns of being flush) with the bottom surface of the package as shown in FIG. 8W1, such as the dielectric layer 808 and the remainder of the metal layer 806. FIG. 8X1 and 8X2 are bottom-up and perspective views of the structure of FIG. 8W1 and 8W2, except that a solder mask layer 830 is applied to the bottom surface of the structure as shown, leaving a perimeter of the bottom surface (i.e., the metal layer 806) uncovered, and defining areas of the metal layer 806 through which the Marchand balun may be accessed. FIG. 8Y1 and 8Y2 are top-down and perspective views of the structure of FIG. 8X1 and 8X2, except that solder bumps 832 are coupled to the exposed areas of the metal layer 806. The solder bumps 832 may be coupled to a PCB, for example.

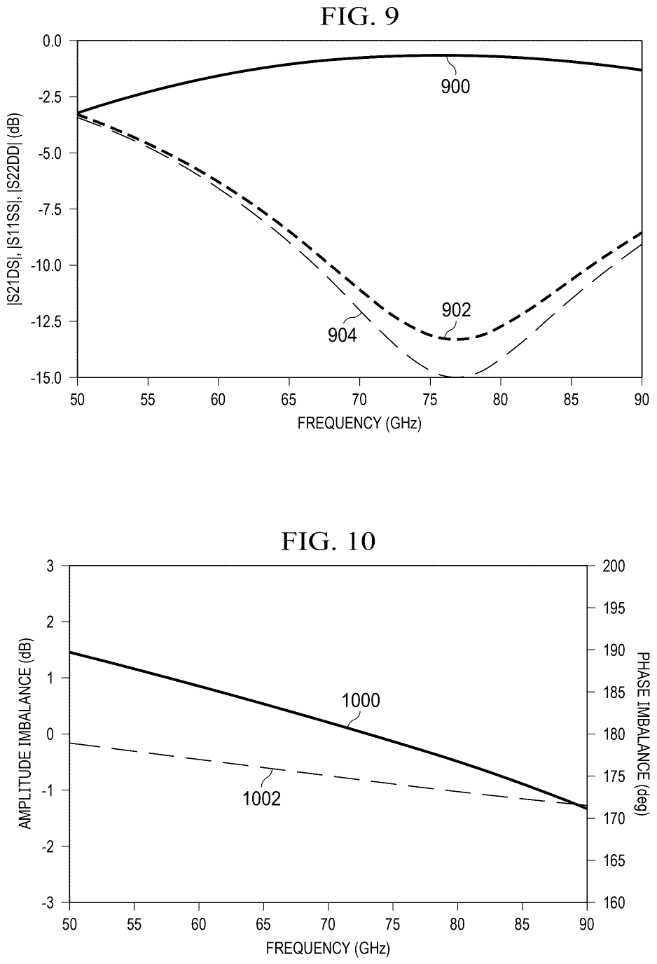

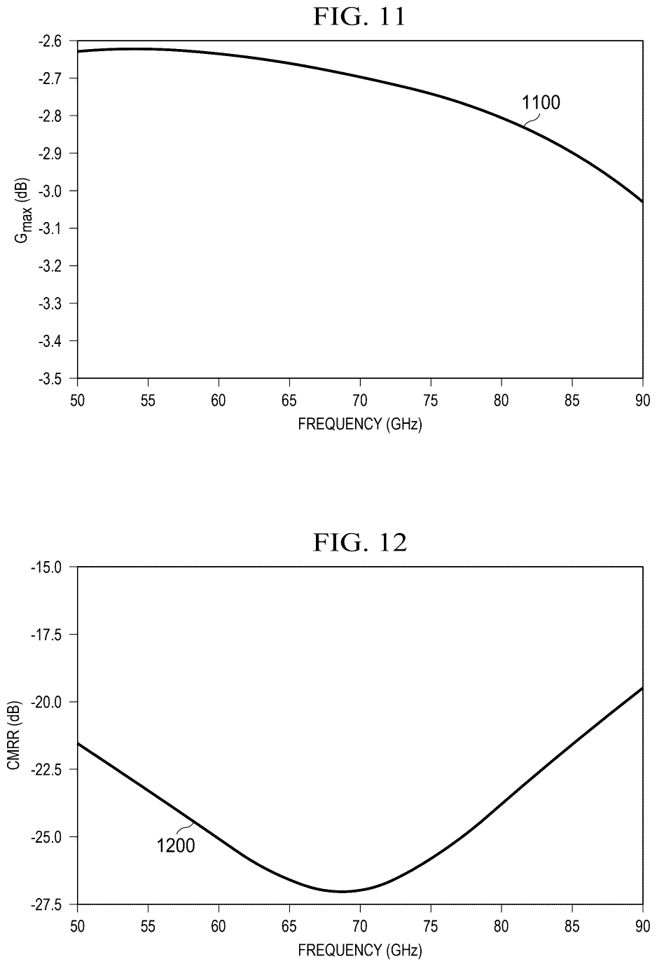

FIGS. 9, 10, 11, and 12 are graphs depicting operational behavior of a semiconductor package including a package substrate having a Marchand balun, such as the various semiconductor packages described herein, in accordance with various examples. In FIG. 9, the graph includes frequency in gigahertz (GHz) on the x-axis and S-parameters in decibels (dB) on the y-axis. The graph includes curves 900, 902, and 904. Curve 900 corresponds to |S_{21DS}|, which is the differential-to-single-ended insertion loss. Curve 902 corresponds to |S_{22DD}|, which is the return loss seen looking into the differential ports (e.g., ends 202, 204). Curve 904 corresponds to |S_{11SS}|, which is the return loss seen looking into the single-ended port (e.g., end 302). The −10 dB return loss bandwidth is 18.5 GHz and the insertion loss is less than 1 dB over this bandwidth (approximately 68 GHz to 85 GHz). In FIG. 10, the graph includes frequency in GHz on the x-axis and amplitude and phase imbalance in dB on the y-axis. The graph includes curves 1000 and 1002. Curve 1000 shows that the amplitude imbalance is less than 1 dB over the return loss bandwidth (approximately 68 GHz to 85 GHz), and curve 1002 shows that the phase imbalance is less than 5 degrees over the same bandwidth. In FIG. 11, the graph includes frequency in GHz on the x-axis and maximum available gain (abbreviated Gmax) in dB on the y-axis. The graph includes curve 1100, which shows that Gmax is greater than −3 dB over the return loss bandwidth of approximately 68 GHz to 85 GHz. In FIG. 12, the graph includes frequency in GHz on the x-axis, and common mode rejection ratio (CMRR) in dB on the y-axis. The graph includes a curve 1200, which shows that the CMRR is less than 20 dB throughout the return loss bandwidth.

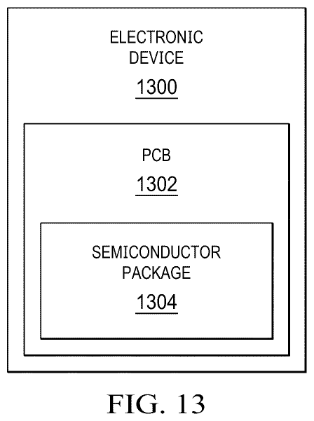

FIG. 13 is a block diagram of an electronic device 1300 including a PCB 1302 to which a semiconductor package 1304 is coupled. Examples of the semiconductor package 1304 include any and all of the semiconductor packages described herein. Examples of the electronic device 1300 include an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Uses of the term “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/-10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a mold compound layer;
a substrate layer contacting the mold compound layer, the substrate layer comprising:
a first copper layer forming a ground plane;
a second copper layer closer to the mold compound layer than the first copper layer, the second copper layer including a first end and a second end opposing the first end, a body of the second copper layer between the first and second ends having an open curve shape in a top view and a first width in the top view;
a third copper layer closer to the mold compound layer than the second copper layer, the third copper layer including a third end and a fourth end opposing the third end, a body of the third copper layer between the third and fourth ends having the open curve shape in the top view and a second width greater than the first width in the top view, the second and third copper layers forming a Marchand balun, the third and fourth ends extending away from the first and second ends in the top view;
a first metal contact coupled to the first end and having a surface that is approximately flush with a surface of the semiconductor package;
a second metal contact coupled to the second end and having a surface that is approximately flush with the surface of the semiconductor package;
a third metal contact coupled to the third end and having a surface that is approximately flush with the surface of the semiconductor package; and
a fourth metal contact coupled to the body of the second copper layer and having a surface that is approximately flush with the surface of the semiconductor package; and
a set of solder bumps contacting the first, second, third, and fourth metal contacts.

2. The semiconductor package of claim 1, wherein each of the second and third copper layers is at least 8 microns in width from a top view.

3. The semiconductor package of claim 1, wherein each of the second and third copper layers has a vertical thickness of at least 12 microns.

4. The semiconductor package of claim 1, wherein a vertical distance between the second and third copper layers is at least 18 microns.

5. The semiconductor package of claim 1, further comprising a set of vias that couple the first, second, third, and fourth metal contacts to the first, second, and third ends and the body of the second copper layer, respectively.

6. The semiconductor package of claim 5, wherein vias in the set of vias have a trapezoidal shape in a profile cross-sectional view.

7. The semiconductor package of claim 1, wherein the fourth metal contact is coupled to the body of the second copper layer at a midpoint of the second copper layer that is equidistant from the first and second ends.

8. The semiconductor package of claim 1, further comprising a metal wall surrounding the first, second, and third copper layers.

9. The semiconductor package of claim 8, wherein the substrate layer comprises a fifth metal contact coupled to the metal wall.

10. The semiconductor package of claim 1, further comprising a first solder mask contacting the first copper layer and a second solder mask contacting the third copper layer.

11. The semiconductor package of claim 1, further comprising a dielectric material between the first and second copper layers and between the second and third copper layers.

12. The semiconductor package of claim 11, wherein the dielectric material includes pre-preg.

13. The semiconductor package of claim 1, wherein the fourth end is not coupled to an electrically conductive structure other than the third copper layer.

14. The semiconductor package of claim 1, further comprising a semiconductor die having a device side in which circuitry is formed, the device side coupled to the first, second, and third metal contacts.

15. A semiconductor package, comprising:
a semiconductor die having a device side in which circuitry is formed;
a substrate layer having a top surface coupled to the semiconductor die, the substrate layer comprising:
a first copper layer forming a ground plane;
a second copper layer closer to the semiconductor die than the first copper layer, the second copper layer including a first open curve-shaped structure having first and second opposing ends and a second open curve-shaped structure having third and fourth opposing ends;
a third copper layer closer to the semiconductor die than the second copper layer, the third copper layer forming a third open curve-shaped structure having fifth and sixth opposing ends;
a first contact coupled to the first end and exposed to an exterior of the substrate layer;
a second contact coupled to the second end and exposed to the exterior of the substrate layer;
a third contact coupled to the third and fourth ends and exposed to the exterior of the substrate layer; and
a fourth contact coupled to the fifth end and exposed to the exterior of the substrate layer; and
a mold compound covering the semiconductor die and the substrate layer.

16. The semiconductor package of claim 15, wherein the third contact is configured to be coupled to ground.

17. The semiconductor package of claim 15, wherein the second and fourth ends are separated from each other.

18. The semiconductor package of claim 15, further comprising a metal wall surrounding the first, second, and third copper layers, the metal wall coupled to the ground plane.

19. The semiconductor package of claim 15, further comprising a first solder mask contacting the first copper layer and a second solder mask contacting the third copper layer.

20. The semiconductor package of claim 15, further comprising a dielectric material between the first and second copper layers, between the second and third copper layers, and between the second and fourth ends.

21. The semiconductor package of claim 15, wherein the sixth end forms an open circuit.

22. A method for manufacturing a semiconductor package, comprising:
depositing first and second metal seed layers on first and second opposing sides of a carrier, respectively;
patterning first and second photoresist layers on the first and second metal seed layers, respectively;
plating first and second metal layers using the first and second metal seed layers and the first and second photoresist layers, respectively, the first and second metal layers forming ground planes;
removing the first and second photoresist layers and portions of the first and second metal seed layers;
applying first and second dielectric layers on the first and second metal layers, respectively;
drilling first and second via holes in the first and second dielectric layers, respectively;
depositing third and fourth metal seed layers on the first and second dielectric layers, respectively, including inside the first and second via holes, respectively;
patterning third and fourth photoresist layers on the third and fourth metal seed layers, respectively;
plating first and second vias in the first and second via holes using the third and fourth metal seed layers, respectively;
plating third and fourth metal layers using the third and fourth metal seed layers and the third and fourth photoresist layers, respectively, the third metal layer including a first end and a second end opposing the first end, the fourth metal layer including a third end and a fourth end opposing the third end, a body of the third metal layer between the first and second ends having an open curve shape and a first width, a body of the fourth metal layer between the third and fourth ends having the open curve shape and a second width, the third and fourth metal layers contacting the first and second vias, respectively;
removing the third and fourth photoresist layers and portions of the third and fourth metal seed layers;
applying third and fourth dielectric layers to the third and fourth metal layers, respectively;
drilling third and fourth via holes in the third and fourth dielectric layers, respectively;
depositing fifth and sixth metal seed layers on the third and fourth dielectric layers, respectively, including inside the third and fourth via holes, respectively;
patterning fifth and sixth photoresist layers on the fifth and sixth metal seed layers, respectively;
plating third and fourth vias in the third and fourth via holes using the fifth and sixth metal seed layers, respectively;
plating fifth and sixth metal layers using the fifth and sixth metal seed layers and the fifth and sixth photoresist layers, respectively, the fifth metal layer including a fifth end and a sixth end opposing the fifth end, a body of the fifth metal layer between the fifth and sixth ends having the open curve shape and a third width greater than the first width, the third and fifth metal layers forming a first Marchand balun, the sixth metal layer including a seventh end and an eighth end opposing the seventh end, a body of the sixth metal layer between the seventh and eighth ends having the open curve shape and a fourth width greater than the second width, the fourth and sixth metal layers forming a second Marchand balun, the fifth and sixth metal layers contacting the third and fourth vias, respectively;
removing the fifth and sixth photoresist layers and portions of the fifth and sixth metal seed layers;
removing the carrier;
applying a first solder mask to the first metal layer and a second solder mask to the fifth metal layer; and
applying a mold compound to the second solder mask.

23. The method of claim 22, wherein the drilling of the first, second, third, and fourth via holes includes laser drilling.

24. The method of claim 22, further comprising forming metal contacts on a bottom surface of the semiconductor package, a first metal contact of the metal contacts coupled to the first metal layer, a second metal contact of the metal contacts coupled to the second metal layer, and a third metal contact of the metal contacts coupled to the third metal layer.

25. The method of claim 22, wherein, in a top view, the bodies of the second and third metal layers do not overlap with each other.
